(19) United States
(12) Patent Application Publication
(10) Pub. No.: US 2026/0182029 A1
(43) Pub. Date: Jun. 25, 2026

(54) ARRAY SUBSTRATE, DISPLAY PANEL, AND MASK

(71) Applicants: Beijing BOE Technology Development Co., Ltd., Beijing (CN); BOE TECHNOLOGY GROUP CO., LTD., Beijing (CN)

(72) Inventors: Shunhang ZHANG, Beijing (CN); Jiahui HAN, Beijing (CN); Tianmin ZHOU, Beijing (CN); Pengxia LIANG, Beijing (CN); Zhenyu ZHANG, Beijing (CN); Minghua XUAN, Beijing (CN); Zhen ZHANG, Beijing (CN); Dongni LIU, Beijing (CN); Yunsik IM, Beijing (CN); Peirou LI, Beijing (CN); Lianfu YU, Beijing (CN); Ruizhi YANG, Beijing (CN); Hui GUO, Beijing (CN)

(21) Appl. No.: 18/849,199

(22) PCT Filed: Sep. 26, 2023
(86) PCT No.: PCT/CN2023/121313

§ 371 Date: Sep. 20, 2024

(51) Int. Cl. H10D 86/40; H10D 86/01

(52) U.S. Cl. CPC H10D 86/441; H10D 86/0231

(57) ABSTRACT

An array substrate includes: a base substrate, and a first auxiliary layer and a plurality of pixel structures, where at least one pixel structure includes: a transistor; a first transfer electrode including first and second transfer parts connected to each other, where the second transfer part is in a first via running through the first auxiliary layer to be electrically connected to the transistor; an auxiliary member in the first via; and a first electrode including a contact part and a body part connected to each other, where the contact part is electrically connected to the first transfer part, and an orthographic projection of the first electrode on the base substrate covers an orthographic projection of the first via on the base substrate; and an orthographic projection of the first transfer part on the base substrate overlaps an orthographic projection of the contact part on the base substrate.

### TECHNICAL FIELD

The present disclosure relates to the field of display technology, and specifically relates to an array substrate, a display panel, and a mask.

### BACKGROUND

Virtual reality/augmented reality (VR/AR) is one of the most popular display technologies now. Most VR products in the existing art have a resolution in the range of 2 k to 4 k, and higher-resolution screens are demanded for future product development. Compared with the organic light-emitting diode (OLED) display technology, the liquid crystal display (LCD) technology is easier to achieve a higher resolution, and therefore has become one of the mainstream display technologies in current VR/AR products.

### SUMMARY

In a first aspect, the present disclosure provides an array substrate, including: a base substrate, and a first auxiliary layer and a plurality of pixel structures on the base substrate, wherein at least one of the pixel structures includes:
a transistor between the first auxiliary layer and the base substrate;
a first transfer electrode including a first transfer part and a second transfer part connected to each other, wherein the first transfer part is on a side of the first auxiliary layer away from the base substrate, and the second transfer part is in a first via running through the first auxiliary layer to be electrically connected to the transistor;
an auxiliary member in the first via; and
a first electrode including a contact part and a body part connected to each other, wherein the contact part is electrically connected to the first transfer part, and an orthographic projection of the first electrode on the base substrate covers an orthographic projection of the first via on the base substrate;
wherein an orthographic projection of the first transfer part on the base substrate is overlapped with an orthographic projection of the contact part on the base substrate.

In some embodiments, the contact part contacts a surface of the first transfer part away from the base substrate, at least a part of the body part is on a surface of the auxiliary member away from the base substrate, and the second transfer part of the first transfer electrode is closer to the base substrate than the auxiliary member.

In some embodiments, at least one side boundary of the orthographic projection of the first transfer part on the base substrate exceeds the orthographic projection of the contact part on the base substrate.

In some embodiments, from a view perpendicular to the base substrate, a boundary of the orthographic projection of the first transfer part on the base substrate exceeds, along a first direction, a boundary of the orthographic projection of the contact part on the base substrate.

In some embodiments, the array substrate further includes: a second auxiliary layer between the first auxiliary layer and the transistor; the at least one of the pixel structures further includes: a second transfer electrode electrically connected to the transistor through a second via running through the second auxiliary layer;
wherein the second via is in communication with the first via, and the first transfer electrode and the second transfer electrode are connected into an integral structure.

In some embodiments, an orthographic projection of an opening of the first via facing the base substrate on the base substrate is not overlapped with an orthographic projection of an opening of the second via facing away from the base substrate on the base substrate.

In some embodiments, the array substrate has a plurality of pixel regions each provided with a corresponding pixel structure; a size of each pixel region in a first direction is greater than a size of the pixel region in a second direction perpendicular to the first direction; and
the contact part is on a side of the body part along the first direction.

In some embodiments, the first transfer part includes a first portion and a second portion, an orthographic projection of the first portion on the base substrate is within the orthographic projection of the contact part on the base substrate, the second portion is on a side of the first portion along the first direction, and an orthographic projection of the second portion on the base substrate is outside the orthographic projection of the contact part on the base substrate; and
a ratio of a size of the first portion to a size of the pixel region in the first direction is between 0.1 and 0.5.

In some embodiments, in a direction perpendicular to the base substrate, the auxiliary member has a height greater than or equal to a depth of the first via.

In some embodiments, in a direction perpendicular to the base substrate, a distance between the body part of the first electrode and the base substrate is greater than a distance between the contact part and the base substrate.

In some embodiments, the second portion has a width less than or equal to 1.5 μm in the first direction.

In some embodiments, at least three of the pixel structures each include an electrode assemble including the first transfer electrode and the first electrode connected to the first transfer electrode in the corresponding pixel region, wherein a first distance is provided between electrode assemblies of two adjacent pixel structures arranged in the first direction, and a ratio of the first distance to a length of the electrode assembly in the first direction is between 0.05 and 0.15.

In some embodiments, the body part includes a first edge and a second edge opposite to each other in the first direction, the first edge is on a side of the body part away from the contact part, the second edge is adjacent to the contact part, and the pixel region has a size between 6 μm and 10 μm in the first direction; and a distance between the first edge and an opening of the first via facing the base substrate in the first direction is between 0 μm and 1.5 μm.

In some embodiments, in a top view from the first auxiliary layer to the base substrate, an opening of the first via away from the base substrate has a plurality of first straight edges and a first arc edge connecting every two adjacent first straight edges; an opening of the first via close to the base substrate has a plurality of second straight edges and a second arc edge connecting every two adjacent second straight edges; and
the first transfer electrode is not in contact with the first arc edge and the second arc edge.

In some embodiments, the second transfer part contacts one of the second straight edges and one of the first straight edges, and a width of the second transfer part is 0.5 to 0.9 times a length of the one of the second straight edges in contact with the second transfer part.

In some embodiments, the pixel structures are in one-to-one correspondence with first vias in the first auxiliary layer; or,
the plurality of pixel structures are arranged in a plurality of rows, and the first vias corresponding to a plurality of pixel structures in the same row are communicated.

In some embodiments, the first vias corresponding to the plurality of pixel structures in the same row are communicated; and a distance in the row direction between second transfer parts of two adjacent first transfer electrodes in the same row is 0.5 to 10 times a width of each second transfer part.

In some embodiments, the array substrate further includes a second electrode layer provided with a slit including a main slit part, and a first corner part and a second corner part at two ends of, and in communication with, the main slit part, and the main slit part extends in a third direction; the first corner part and the second corner part are respectively bent towards two opposite sides of the main slit part;
the first transfer electrode forms an electrode assembly with the corresponding first electrode, an orthographic projection of the main slit part on the base substrate is within an orthographic projection of the electrode assembly on the base substrate, and orthographic projections of the first corner part and the second corner part on the base substrate are both overlapped with the orthographic projection of the electrode assembly on the base substrate.

In some embodiments, the main slit part has a width between 0.5 μm and 3 μm in a direction perpendicular to the third direction.

In some embodiments, the main slit part includes a first side edge and a second side edge arranged in a width direction of the main slit part, the first corner part is bent in a direction away from the second side edge toward the first side edge, and the second corner part is bent in a direction away from the first side edge toward the second side edge;
the first corner part includes a first connecting edge connected to the first side edge, and an angle of 30° to 60° is formed between a tangent line at a joint of the first connecting edge and the first side edge and the second direction; the second corner part includes a second connecting edge connected to the first side edge and a third connecting edge connected to the second connecting edge, and an angle of 15° to 30° is formed between a tangent line at an end of the third connecting edge away from the second connecting edge and the second direction; and the second direction is perpendicular to the first direction.

In some embodiments, an angle between the third direction and the first direction is in a range of [0°, 30°].

In some embodiments, the second electrode layer is provided with the slit at a position corresponding to each electrode assembly,
the plurality of pixel structures are arranged in a plurality of rows in the first direction, each row including a plurality of pixel structures arranged in the second direction, the first corner part of the slit corresponding to at least one pixel structure is in communication with the second corner part of the slit corresponding to one pixel structure in a previous row, and the second corner part of the slit corresponding to at least one pixel structure is in communication with the first corner part of the slit corresponding to one pixel structure in a next row.

In some embodiments, a plurality of slits in the second electrode layer are divided into a plurality of slit groups, the slits in the same slit group are communicated with each other to form a dividing groove, and a plurality of dividing grooves corresponding to the plurality of slit groups divide the second electrode layer into a plurality of second electrode strips; and
the array substrate further includes a plurality of connection electrodes extending in the second direction and electrically connected to the plurality of second electrode strips.

In some embodiments, orthographic projections of each connection electrode and the main slit part of the corresponding slit on the base substrate are not overlapped with each other.

In some embodiments, the connection electrode has a width between 1.2 μm and 2.4 μm in a direction perpendicular to the second direction.

In a second aspect, the present disclosure further provides a display panel, including the array substrate as described above.

In some embodiments, the display panel further includes an opposite substrate opposite to the array substrate, the opposite substrate includes a black matrix, and orthographic projections of the body part and the first transfer part on the base substrate are both overlapped with an orthographic projection of the black matrix on the base substrate.

In some embodiments, the display panel further includes an opposite substrate opposite to the array substrate, the opposite substrate includes a black matrix, and orthographic projections of the first via and the black matrix on the base substrate are not overlapped with each other.

In a third aspect, the present disclosure further provides a mask used in a method for manufacturing an array substrate, wherein the array substrate is an array substrate as described above, and the mask includes: a light-transmitting region for forming the first via, wherein an orthographic projection of the first via on the base substrate has a substantially polygonal shape, the light-transmitting region includes a main light-transmitting region and a compensation light-transmitting region communicated with each other, the main light-transmitting region has a polygonal shape, the compensation light-transmitting region is at a corner of the main light-transmitting region, and the compensation light-transmitting region protrudes out of edges of the main light-transmitting region in both a length direction and a width direction of the main light-transmitting region.

In some embodiments, the compensation light-transmitting region exceeds the main light-transmitting region in the length direction of the main light-transmitting region by a size of 0.02 to 0.2 times a length of the main light-transmitting region; and the compensation light-transmitting region exceeds the main light-transmitting region in the width direction of the main light-transmitting region by a size of 0.02 to 0.2 times a width of the main light-transmitting region.

### BRIEF DESCRIPTION OF DRAWINGS

Accompanying drawings are provided for further understanding of the present disclosure and constitute a part of the specification. Hereinafter, these drawings are intended to explain the present disclosure together with the following specific implementations, but should not be considered as a limitation on the present disclosure.

In the drawings:

FIG. 1 is a schematic diagram showing a part of a structure of an array substrate according to some embodiments.

FIG. 2 is a schematic diagram showing a positional relationship of a data line, a first electrode, a first transfer electrode, and a light-shielding layer according to some embodiments.

FIG. 3 is a schematic diagram showing a part of a structure of an array substrate according to some embodiments of the present disclosure.

FIG. 4 is a schematic diagram showing relevant dimensions in the array substrate shown in FIG. 3.

FIG. 5 is a plan view of a first transfer electrode, a first electrode, a first via, and a second via in the array substrate shown in FIG. 3.

FIG. 6 is a schematic diagram of a pixel region according to some embodiments of the present disclosure.

FIG. 7 is a diagram showing a comparison of electrode assemblies in a comparative example and the present disclosure.

FIG. 8 is a schematic diagram showing a part of a structure of an array substrate according to some other embodiments of the present disclosure.

FIG. 9 is a schematic diagram showing relevant dimensions in the array substrate shown in FIG. 8.

FIG. 10 is a plan view of a first transfer electrode, a first electrode, a first via, and a second via in the array substrate shown in FIG. 8.

FIG. 11 is a schematic diagram showing a light leakage position of the first via.

FIGS. 12 and 13 are two plan views of a first transfer electrode, a first via, and a second via according to some embodiments of the present disclosure.

FIG. 14 is a plan view of a plurality of first transfer electrodes and first vias in the same row according to some embodiments of the present disclosure.

FIG. 15 is a plan view of a plurality of first transfer electrodes and first vias in the same row according to some other embodiments of the present disclosure.

FIG. 16 is a schematic diagram of an array substrate provided with a second electrode layer according to some embodiments of the present disclosure.

FIG. 17 is a plan view of a second electrode layer in a single pixel region relative to a first electrode and a first transfer electrode.

FIG. 18 is a schematic diagram showing luminance distribution of the pixel region corresponding to FIG. 17.

FIG. 19 is a plan view of a second electrode layer in a single pixel region relative to a first electrode and a first transfer electrode according to some other embodiments of the present disclosure.

FIG. 20 is a schematic diagram showing luminance distribution of the pixel region corresponding to FIG. 19.

FIG. 21 is a schematic diagram showing slits in a second electrode layer not misaligned and misaligned with an electrode assembly, respectively.

FIG. 22 is a schematic diagram of a second electrode layer according to some embodiments of the present disclosure.

FIG. 23 is a diagram showing a superposition of a plurality of electrode assemblies, a second electrode layer and a connection electrode according to some embodiments of the present disclosure.

FIG. 24 is a diagram showing a simulation of light transmittances of a pixel region under different conditions.

FIG. 25 is a plan view of a semiconductor layer according to some embodiments of the present disclosure.

FIG. 26 is a plan view of a gate metal layer according to some embodiments of the present disclosure.

FIG. 27 is a plan view of a first interlayer dielectric layer according to some embodiments of the present disclosure.

FIG. 28 is a plan view of a source-drain metal layer according to some embodiments of the present disclosure.

FIG. 29 is a plan view of a second interlayer dielectric layer according to some embodiments of the present disclosure.

FIG. 30 is a diagram showing a superposition of a gate metal layer, a first interlayer dielectric layer, a source-drain metal layer, and a second interlayer dielectric layer according to some embodiments of the present disclosure.

FIG. 31 is a plan view of a first transparent conductive layer according to some embodiments of the present disclosure.

FIG. 32 is a diagram showing a superposition of a first transparent conductive layer and a second interlayer dielectric layer according to some embodiments of the present disclosure.

FIG. 33 is a plan view of a planarization layer according to some embodiments of the present disclosure.

FIG. 34 is a diagram showing a superposition of a second interlayer dielectric layer, a first transparent conductive layer, and a planarization layer according to some embodiments of the present disclosure.

FIG. 35 is a plan view of a second transparent conductive layer according to some embodiments of the present disclosure.

FIG. 36 is a diagram showing a superposition of a second interlayer dielectric layer, a first transparent conductive layer, a second transparent conductive layer, and a planarization layer according to some embodiments of the present disclosure.

FIG. 37 is a plan view of a third transparent conductive layer according to some embodiments of the present disclosure.

FIG. 38 is a diagram showing a superposition of a second interlayer dielectric layer, a first transparent conductive layer, a second transparent conductive layer, a planarization layer, and a third transparent conductive layer according to some embodiments of the present disclosure.

FIG. 39 is a plan view of a second electrode layer according to some embodiments of the present disclosure.

FIG. 40 is a diagram showing a superposition of a second interlayer dielectric layer, a first transparent conductive layer, a second transparent conductive layer, a planarization layer, a third transparent conductive layer, and a second electrode layer according to some embodiments of the present disclosure.

FIG. 41 is a plan view of a black matrix relative to a first electrode and a first transfer electrode according to some embodiments of the present disclosure.

FIG. 42 is a plan view of a black matrix relative to a second electrode layer according to some embodiments of the present disclosure.

FIG. 43 is a schematic diagram showing a part of a mask according to some embodiments of the present disclosure.

FIG. 44 is a schematic diagram showing a part of a mask according to some other embodiments of the present disclosure.

FIG. 45 is a schematic diagram showing a part of a mask according to yet other embodiments of the present disclosure.

FIG. 46 is a schematic diagram showing a part of a mask according to still other embodiments of the present disclosure.

FIG. 47 is a schematic diagram of a display panel and a flexible printed circuit according to some embodiments of the present disclosure.

FIG. 48 is a schematic diagram of an application scenario of a display panel according to some embodiments of the present disclosure.

FIG. 49 is a schematic diagram of a near eye display device.

### DETAIL DESCRIPTION OF EMBODIMENTS

Hereinafter, specific implementations of the present disclosure will be described with respect to the accompanying drawings. It will be appreciated that the specific implementations as set forth herein are merely for the purpose of illustration and explanation of the present disclosure, and should not be constructed as a limitation thereon.

To make the objects, technical solutions and advantages of the embodiments of the present disclosure more apparent, the technical solutions according to the embodiments of the present disclosure will be clearly and completely described below with reference to the drawings of the embodiments of the present disclosure. Apparently, the described embodiments are some, but not all, of the embodiments of the present disclosure. All other embodiments obtained by one of ordinary skill in the art based on the embodiments of the present disclosure described herein without paying any creative effort shall be included in the protection scope of the present disclosure.

Unless otherwise defined, technical or scientific terms used in the embodiments of the present disclosure are intended to have general meanings as understood by one of ordinary skill in the art to which the present disclosure belongs. The words “first”, “second” and the like used in the present disclosure do not denote any order, quantity, or importance, but are used merely for distinguishing different components from each other. Likewise, the word “comprising” or “including” or the like means that the element or item preceding the word contains elements or items that appear after the word or equivalents thereof, but does not exclude other elements or items. The words “connected” or “coupled” and the like are not restricted to physical or mechanical connections, but may include electrical connections, whether direct or indirect. The words “upper”, “lower”, “left”, “right”, and the like are merely used to indicate a relative positional relationship, and when an absolute position of the described object is changed, the relative positional relationship may be changed accordingly.

As used herein, “about”, “around” or “approximately” includes the stated value as well as average values within an acceptable range of deviation for the particular value as determined by one of ordinary skill in the art in view of the measurement in question and the error associated with measuring the particular quantity (i.e., the limitations of the measurement system).

As used herein, “parallel” or “perpendicular” includes the recited case and cases that approximate the recited case to within an acceptable range of deviation as determined by one of ordinary skill in the art in view of the measurement in question and the error associated with the measurement of the particular quantity (i.e., the limitations of the measurement system). For example, “parallel” includes “absolutely parallel” and “approximately parallel”, where an acceptable deviation of “approximately parallel” may be, for example, within 5°; and “perpendicular” includes “absolutely perpendicular” and “approximately perpendicular”, where an acceptable deviation of “approximately perpendicular” may also be, for example, within 5°.

It will be understood that when a layer or element is referred to as being “on” another layer or substrate, it may be directly on the other layer or substrate, or intervening layers may be present therebetween.

Exemplary implementations are described herein with reference to cross-sectional and/or plan views as idealized exemplary figures. In the drawings, the thicknesses of layers and regions are exaggerated for clarity. Variations from the shapes in the figures as a result of, for example, manufacturing techniques and/or tolerances, are to be expected. Therefore, exemplary implementations should not be construed as limited to the shapes of regions illustrated herein, but are to include deviations in shapes that result, for example, from manufacturing. For example, an etched region shown as a rectangle will typically have curved features. Therefore, the regions illustrated in the figures are schematic in nature, and their shapes are not intended to illustrate the actual shape of a region of a device, or intended to limit the scope of exemplary implementations.

As used herein, the circular, triangular, rectangular, trapezoidal, pentagonal or hexagonal shape or the like is not meant to be strict, and may include an approximately circular, triangular, rectangular, trapezoidal, pentagonal or hexagonal shape, or the like, and some minor variations due to tolerances, as well as lead angles, curved edges, variations, or the like, may exist.

In the various implementations herein, a direction from the base substrate toward the first auxiliary layer is referred to as “up” or “upward”. Conversely, a direction from the first auxiliary layer toward the base substrate is referred to as “down” or “downward”. As described above, for convenience of explanation, the description is given using the term “above” or “under”, but the base substrate and the first auxiliary layer may be arranged such that the vertical relationship therebetween is reversed from that shown in the figures. The above description is merely for describing the vertical relationship between the base substrate and the first auxiliary layer, and other members may be disposed between the base substrate and the first auxiliary layer. The words “above” or “under” refers to a stacking order in a structure in which a plurality of layers are stacked, and the first electrode above the transistor may refer to a positional relationship in which the transistor is not overlapped with the first electrode in a top view. On the other hand, the first electrode vertically above the transistor refers to a positional relationship in which the transistor is overlapped with the first electrode in a top view.

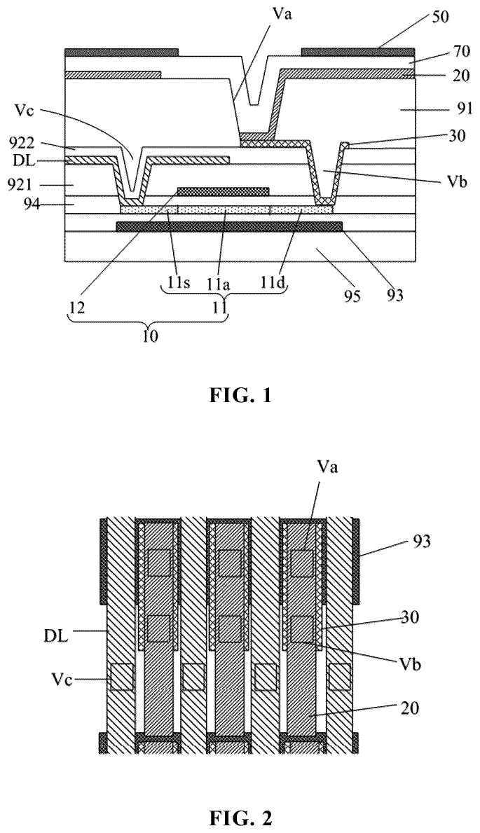

A liquid crystal display panel includes an array substrate and an opposite substrate disposed opposite to each other, and a liquid crystal layer between the array substrate and the opposite substrate. FIG. 1 is a schematic diagram showing a part of a structure of an array substrate according to some embodiments, and FIG. 2 is a schematic diagram showing a positional relationship of a data line, a first electrode, a first transfer electrode, and a light-shielding layer according to some embodiments. The display panel includes a plurality of pixel regions, FIG. 1 shows a structure corresponding to only one pixel region, and the structure shown in FIG. 1 may be applied to a display product with a relatively high pixel density, for example, a pixel density in the range of 1000 PPI (pixels per inch) to 1500 PPI.

As shown in FIG. 1, the array substrate includes a plurality of pixel structures on a base substrate 95, and each pixel structure includes a thin film transistor, a transfer electrode, and a first electrode 20. Taking the thin film transistor being a top gate thin film transistor as an example, a gate 12 of the thin film transistor is located on a side of an active layer 11 away from the base substrate 95, and the active layer 11 includes a channel region 11a, and a source region 11s and a drain region 11d on two sides of the channel region 11a. A gate insulator layer 94 is disposed between the gate 12 and the active layer 11, a first auxiliary sub-layer 921 is disposed on a side of the gate 12 away from the base substrate 95, a second auxiliary sub-layer 922 is disposed on a side of a layer where data lines DL are located away from the base substrate 95, and a first auxiliary layer 91 is disposed on a side of the second auxiliary sub-layer 922 away from the base substrate 95.

Each data line DL is connected to the source region 11s through a via running through the first auxiliary sub-layer 921 and the gate insulator layer 94, and the transfer electrode is connected to the drain region 11d through a via running through the second auxiliary sub-layer 922, the first auxiliary sub-layer 921, and the gate insulator layer 94. The first electrode 20 is located on a side of the first auxiliary layer 91 away from the base substrate 95, and electrically connected to the first transfer electrode 30 through a via Va in the first auxiliary layer 91. An insulating spacer layer 70 is disposed on a side of the first electrode 20 away from the base substrate 95, and a second electrode layer 50 is disposed on a side of the insulating spacer layer 70 away from the base substrate 95. The first transfer electrode 30 is made of a transparent material such as indium tin oxide (ITO), which can reduce the influence on the aperture ratio of the pixel region. In addition, since the via Va is relatively deep, a large step is present between one portion of the first electrode 20 in the via Va and the other portion of the first electrode 20 outside the via Va, which may affect an orientation of the liquid crystal above the via Va and then cause light leakage. To prevent the influence on the orientation of the liquid crystal due to the deep via Va, as shown in FIGS. 1 and 2, a light-shielding layer 93 is provided on the base substrate 95 to shield the via Va.

However, for a product with a higher pixel density (e.g., greater than or equal to 2000 PPI), the size of the pixel region is typically small, and the provision of the light-shielding layer 93 may have a great influence on the aperture ratio of the pixel region. Also, due to the limited size of the pixel region, the first electrode 20 has a limited size and forms a limited electric field region with the second electrode layer 50, resulting in low liquid crystal efficiency.

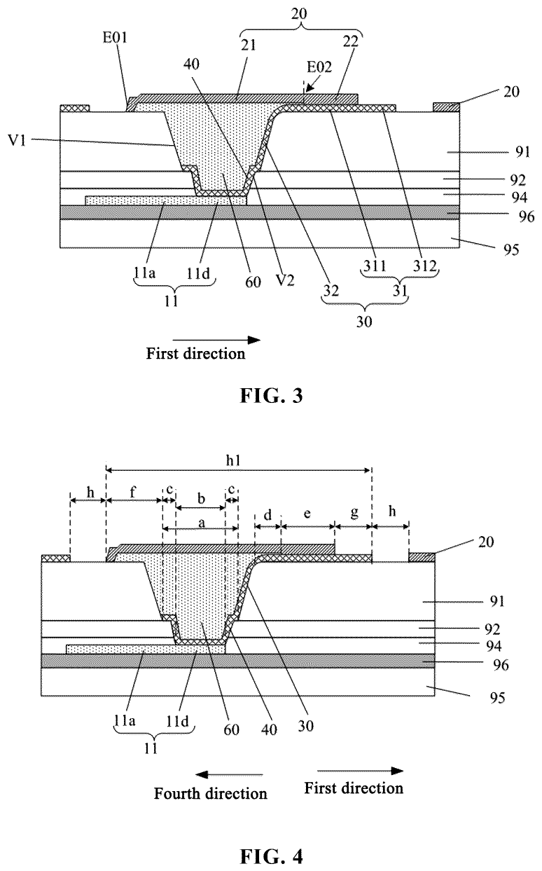

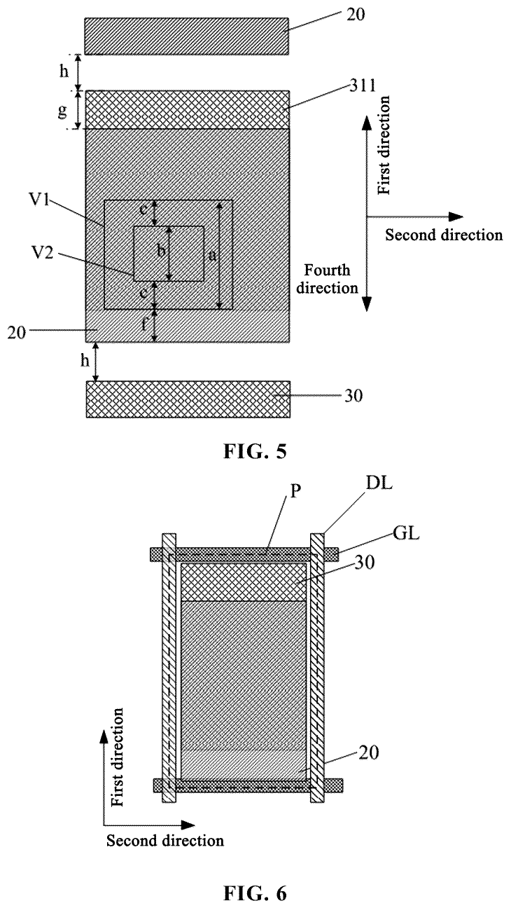

The present disclosure provides an array substrate. FIG. 3 is a schematic diagram showing a part of a structure of an array substrate according to some embodiments of the present disclosure, FIG. 4 is a schematic diagram showing relevant dimensions in the array substrate shown in FIG. 3, and FIG. 5 is a plan view of a first transfer electrode, a first electrode, a first via, and a second via in the array substrate shown in FIG. 3. The array substrate may include a plurality of gate lines and a plurality of data lines on the base substrate 95. The plurality of gate lines and the plurality of data lines define a plurality of pixel regions, and FIG. 3 merely shows a structure corresponding to one of the pixel regions. As shown in FIG. 3, the array substrate includes: a base substrate 95, a first auxiliary layer 91 and a plurality of pixel structures on the base substrate 95. Each pixel structure corresponds to one of the pixel regions. At least one of the pixel structures includes: a transistor, a first transfer electrode 30, a light-transmitting auxiliary member (filling part) 60, and a first electrode 20.

The transistor may include a thin film transistor (TFT) or a field effect transistor such as a metal-oxide-semiconductor (MOS), and the thin film transistor is taken as an example for illustration in the present disclosure. The thin film transistor is located between the first auxiliary layer 91 and the base substrate 95. The first transfer electrode 30 includes a first transfer part 31 and a second transfer part 32 connected to each other. The first transfer part 31 is located on a side of the first auxiliary layer 91 away from the base substrate 95; and the second transfer part 32 is disposed in the first via V1 and electrically connected to the thin film transistor. The first via V1 runs through the first auxiliary layer 91.

The auxiliary member 60 is positioned in the first via V1. In one example, a surface of the auxiliary member 60 away from the base substrate 95 may be substantially flush with a surface of the first auxiliary layer 91 away from the base substrate 95. For example, a height difference between the two surfaces is less than or equal to a thickness of the first electrode 20. In one example, the auxiliary member 60 may be made of a light-transmitting material.

In the embodiments of the present disclosure, the first electrode 20 being a pixel electrode is taken as an example for illustration. The first electrode 20 includes a contact part 22 and a body part 21 connected to each other, where the contact part 22 is electrically connected to the first transfer part 31. For example, the contact part 22 contacts a surface of the first transfer part 31 away from the base substrate 95, and at least a part of the body part 21 is located on a surface of the auxiliary member 60 away from the base substrate 95. An orthographic projection of the first electrode 20 on the base substrate 95 covers an orthographic projection of the first via V1 on the base substrate 95. An orthographic projection of the first transfer part 31 on the base substrate 95 is overlapped with an orthographic projection of the contact part 22 on the base substrate 95. The first transfer electrode 30 and the first electrode 20 may be both made of a transparent conductive material, such as ITO, IZO, ZTO, or the like.

In an embodiment of the present disclosure, the light-transmitting auxiliary member 60 is filled into the first via V1, so that the first electrode 20 may be located on a substantially flat surface, and the first electrode 20 is prevented from having a large step at the position of the first via V1 to affect the electric field distribution. In this case, the light-shielding layer 93 in FIGS. 1 and 2 is omitted, thereby improving the aperture ratio of the pixel region.

In some embodiments, the active layer 11 may be made of a material of high mobility and high light stability, so that a separate light-shielding layer 93 is omitted, and the aperture ratio of the pixel region is further increased.

In some embodiments, the contact part 22 of the first electrode 20 contacts a surface of the first transfer part 31 of the first transfer electrode 30 away from the base substrate 95, and at least a part of the body part 21 is located on a surface of the auxiliary member 60 away from the base substrate 95; and the second transfer part 32 is closer to the base substrate 95 than the auxiliary member 60.

In some embodiments, as shown in FIGS. 3 to 5, at least one side boundary of the orthographic projection of the first transfer part 31 on the base substrate 95 exceeds the orthographic projection of the contact part 22 on the base substrate 95. Since the first electrode 20 is electrically connected to the first transfer part 31, that is, it is an electrode assembly formed by the first electrode 20 connected to the first transfer part 31 that functions on liquid crystal in the pixel region. Moreover, since at least one side boundary of the orthographic projection of the first transfer part 31 on the base substrate 95 exceeds the orthographic projection of the contact part 22 on the base substrate 95, compared with the first electrode 20, the electrode assembly formed by the first electrode 20 connected to the first transfer part 31 is longer in the total length, so that the liquid crystal efficiency at edge positions of the pixel region can be increased, while the influence of an electric field of a metal wire below can be shielded.

As shown in FIGS. 3 to 5, from a view perpendicular to the base substrate 95, a boundary of the orthographic projection of the first transfer part 31 on the base substrate 95 exceeds, along a first direction, a boundary of the orthographic projection of the contact part 22 on the base substrate 95. However, the boundary of the orthographic projection of the first transfer part 31 on the base substrate 95 does not exceed, along a fourth direction parallel to and pointing opposite to the first direction, the boundary of the orthographic projection of the contact part 22 on the base substrate 95. For example, the first direction is a direction from bottom to top in FIG. 5, the fourth direction is a direction from top to bottom in FIG. 5, and an upper boundary of the orthographic projection of the first transfer part 31 exceeds a boundary of the orthographic projection of the contact part 22; while a lower side boundary of the orthographic projection of the first transfer part 31 does not exceed the boundary of the orthographic projection of the contact part 22.

In some embodiments, as shown in FIGS. 3 and 4, in a direction perpendicular to the base substrate 95, the auxiliary member 60 has a height greater than or equal to a depth of the first via V1. Specifically, a distance from the surface of the auxiliary member 60 away from the base substrate 95 to the base substrate 95 is greater than or equal to a distance from a top opening of the first via V1 away from the base substrate 95 to the base substrate 95, so that the first via V1 is ensured to be sufficiently filled by the auxiliary member 60.

In some embodiments, in a direction perpendicular to the base substrate 95, a distance between the body part 21 and the base substrate 95 is greater than a distance between the contact part 22 and the base substrate 95. The distance between the body part 21 and the base substrate 95 is a distance from a surface of the body part 21 facing the auxiliary member 60 to the base substrate 95; and the distance between the contact part 22 and the base substrate 95 is a distance from a surface of the contact part 22 facing the first transfer part 31 to the base substrate 95.

In some embodiments, as shown in FIG. 3, a buffer layer 96 is disposed on the base substrate 95, so that diffusion of metal atoms and/or impurities from the base substrate 95 into the active layer 11 can be prevented or reduced. In one example, the buffer layer 96 may include an inorganic material such as SiOx, SiNx, and/or SiON, and may be formed as a multi-layer or single-layer structure.

The active layer 11 is disposed on a side of the buffer layer 96 away from the base substrate 95. In an embodiment of the present disclosure, the active layer 11 may be made of one or more materials selected from IGZO, IGTO and ITZO, IGO, IGZTO, IZO, ZTO, In-free OS, and Ln-OS. The material of the active layer 11 may be in an amorphous state, a partially crystalline state, a monocrystal state, or a polycrystal state, and may be a single-layer or multi-layer structure, so that the active layer 11 can achieve a higher mobility, which is favorable for reducing the size of the thin film transistor and improving the pixel density of the display substrate. The active layer 11 includes a channel region 11a, and a source region (not shown) and a drain region 11d on two sides of the channel region 11a, and the source region and the drain region 11d may each include impurities of a higher concentration than those in the channel region 11a.

A gate insulator layer 94 is disposed on a side of the active layer 11 away from the base substrate 95. The gate insulator layer 94 may be a full-layer structure; or, the gate insulator layer 94 merely covers the channel region 11a. The gate insulator layer may include, for example, a silicon compound or a metal oxide. For example, the gate insulator layer 94 may include SiON, SiOx, SiNx, SiOxCy, SiCxNy, AlOx, AlNx, TaOx, HfOx, ZrOx, TiOx, or the like. The gate insulator layer 94 may be formed as a single-layer or multi-layer structure.

A second auxiliary layer 92 is located on a side of the gate insulator layer 94 away from the base substrate 95. The second auxiliary layer 92 may be made of a material selected from the materials listed above for the gate insulator layer 94, which will not be repeated here.

The first auxiliary layer 91 is located on a side of the second auxiliary layer 92 away from the base substrate 95. The first auxiliary layer 91 may include an organic insulating material, including, for example, a resin-based material such as polyimide, epoxy, acryl, polyester, photoresist, polyacrylate, polyamide, siloxane, or the like. As another example, the organic insulating material includes an elastic material, such as urethane, thermoplastic polyurethane (TPU), or the like.

The first transfer electrode 30 includes a first transfer part 31 and a second transfer part 32 connected to each other. The first transfer part 31 is located on a side of the first auxiliary layer 91 away from the base substrate 95, and the second transfer part 32 is disposed in the first via V1. As shown in FIG. 3, the pixel structure further includes a second transfer electrode 40 electrically connected to the drain region 11d of the thin film transistor through a second via V2. The second via V2 runs through at least the second auxiliary layer 92. For example, where the gate insulator layer 94 merely covers the channel region 11a of the active layer 11, the second via V2 merely runs through the second auxiliary layer 92; and where the gate insulator layer 94 is a full-layer structure, the second via V2 runs through the second auxiliary layer 92 and the gate insulator layer 94.

In some embodiments, as shown in FIG. 3, the first via V1 is in communication with the second via V2. For example, the first via V1 and the second via V2 are coaxially arranged. An orthographic projection of the second via V2 on the base substrate 95 is located within an orthographic projection of the first via V1 on the base substrate 95.

As shown in FIG. 3, each of the first via V1 and the second via V2 has an opening toward the base substrate 95 and an opening away from the base substrate 95, and for convenience of description, the opening of each via toward the base substrate 95 will be referred to as the bottom opening of the via below, and the opening of the via away from the base substrate 95 will be referred to as the top opening of the via. In one example, an orthographic projection of the bottom opening of either via on the base substrate 95 is located within an orthographic projection of the top opening of the same via on the base substrate 95. As shown in FIG. 3, an orthographic projection of the top opening of the second via V2 on the base substrate 95 is located within an orthographic projection of the bottom opening of the first via V1 on the base substrate 95.

FIG. 6 is a schematic diagram of a pixel region according to some embodiments of the present disclosure. As shown in FIG. 6, in some embodiments, a plurality of gate lines GL and a plurality of data lines DL are further provided on the base substrate 95. The plurality of gate lines GL and the plurality of data lines DL are intersected to define a plurality of pixel regions P, which may include, for example, a plurality of red pixel regions, a plurality of green pixel regions, and a plurality of blue pixel regions. Each pixel region P is provided with a pixel structure. At least three pixel structures (e.g., pixel structures in at least one red pixel region, at least one green pixel region, and at least one blue pixel region) each include an electrode assembly including the first transfer electrode 30 and the first electrode 20 connected to the first transfer electrode 30 in the corresponding pixel region P. A size of the pixel region P in a first direction is greater than a size of the pixel region P in a second direction perpendicular to the first direction. For example, the first direction is an arrangement direction of the plurality of gate lines GL, and the second direction is an extending direction of the gate lines GL. The contact part 22 is located on a side of the body part 21 along the first direction, and a portion of the first transfer electrode 30 is located beyond the first electrode 20, and on a side of the first electrode 20 along the first direction.

In some embodiments, the array substrate has a pixel density greater than or equal to 2000 PPI, and the pixel region P has a size between 6 μm and 10 μm, e.g., 8 μm in the first direction; and the pixel region P has a size between 5 μm and 7 μm, e.g., 6 μm in the second direction. The size of the pixel region P in the first direction is equal to a distance between center lines of two adjacent gate lines GL; and the size of the pixel region P in the second direction is equal to a distance between center lines of two adjacent data lines DL. It should be noted that FIG. 6 merely takes the gate lines GL and the data lines DL being straight lines as an example for illustration, but in other embodiments, either the gate lines GL or the data lines DL may be bent lines. Relevant parameters in FIG. 3 will be described below by taking a pixel region P of 6 μm*8 μm as an example.

As shown in FIGS. 3 to 5, the bottom opening of the first via V1 is substantially rectangular, and a length direction and a width direction thereof are the first direction and the second direction, respectively. In one example, the bottom opening of the first via V1 has a size a between 2.5 μm and 4 μm in the first direction, for example, 2.5 μm, or 3 μm, or 3.5 μm, or 4 μm. A size of the bottom opening of the first via V1 in the second direction may be equal to a, that is, the bottom opening of the first via V1 has a right-angled or rounded square shape.

As shown in FIGS. 3 to 5, the bottom opening of the second via V2 is substantially rectangular, and a length direction and a width direction thereof are the first direction and the second direction, respectively. In one example, the bottom opening of the second via V2 has a size b between 1.0 μm and 2.0 μm in the first direction, for example, 1.0 μm, or 1.5 μm, or 1.8 μm, or 2 μm. A size of the bottom opening of the second via V2 in the second direction may be equal to b, that is, the bottom opening of the second via V2 has a right-angled or rounded square shape.

As shown in FIGS. 3 to 5, a distance c between the bottom opening of the first via V1 and the bottom opening of the second via V2 in the first direction is less than 1 μm. For example, c is 0.2 μm, or 0.4 μm, or 0.6 μm, or 0.8 μm, or 1 μm.

As shown in FIGS. 3 to 5, the first transfer part 31 includes a first portion 311 and a second portion 312. The first portion 311 is a region where the first transfer part 31 directly contacts the contact part 22 of the first electrode 20; and the second portion 312 is a region where the first transfer part 31 goes beyond the first electrode 20 in the first direction. An orthographic projection of the first portion 311 on the base substrate 95 is located within the orthographic projection of the contact part 22 on the base substrate 95, the second portion 312 is located on a side of the first portion 311 along the first direction, and an orthographic projection of the second portion 312 on the base substrate 95 is outside the orthographic projection of the contact part 22 on the base substrate 95.

A ratio of a size of the first portion 311 to a size of the pixel region P in the first direction is between 0.1 and 0.5, so that the secured connection between the first electrode 20 and the first transfer electrode 30 is ensured, and the length of the electrode assembly formed by the first electrode 20 and the first transfer electrode 30 is increased as much as possible. For example, the ratio is 0.1, or 0.2, or 0.3, or 0.4, or 0.5. In one example, the pixel region P has a size between 6 μm and 10 μm in the first direction, and the first portion 311 has a size e between 1 μm and 3 μm in the first direction, so that the secured connection between the first electrode 20 and the first transfer electrode 30 is ensured, and the length of the electrode assembly formed by the first electrode 20 and the first transfer electrode 30 is increased as much as possible. For example, e is 1 μm, or 1.5 μm, or 2 μm, or 2.5 μm, or 3 μm.

A distance d between the first portion 311 and the top opening of the first via V1 in the first direction is 0 μm to 2 μm, thereby ensuring sufficient filling of the auxiliary member 60 into the first via V1 without affecting the width e of the first portion 311. For example, d is 0 μm, or 0.5 μm, or 1 μm, or 1.5 μm, or 2 μm.

The second portion 312 has a width g less than or equal to 1.5 μm in the first direction, so that the contact area between the first electrode 20 and the first transfer electrode 30 is increased as much as possible under a given length of the electrode assembly, thereby ensuring the secured connection between the first electrode 20 and the first transfer electrode 30. In one example, g is between 0.5 μm and 1.5 μm. For example, g is 0.5 μm, or 0.7 μm, or 0.9 μm, or 1.1 μm, or 1.3 μm, or 1.5 μm.

A first distance h is provided between the electrode assemblies of two adjacent pixel structures arranged in the first direction, and a ratio of the first distance h to a length h1 of each electrode assembly in the first direction is between 0.05 and 0.15, so that the electrode assembly has a sufficient length, and a short circuit between two adjacent electrode assemblies in the first direction is prevented. For example, the ratio of h to h1 is 0.05, or 0.07, or 0.09, or 0.1, or 0.11, or 0.13, or 0.15. For example, the pixel region P has a size of 8 μm in the first direction and the first distance h is between 0.5 μm and 2 μm. For example, h is between 0.5 μm and 1.5 μm.

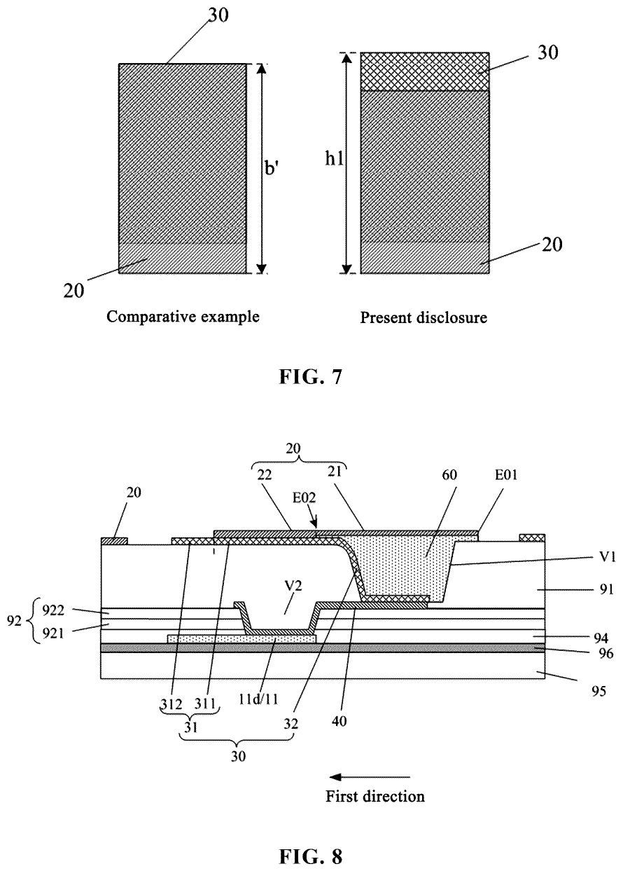

For example, h is 0.5 μm, or 0.75 μm, or 1 μm, or 1.25 μm, or 1.5 μm. The length h1 is between 6.5 μm and 7.5 μm. For example, h1 is 6.5 μm, or 7 μm, or 7.25 μm, or 7.5 μm. FIG. 7 is a diagram showing a comparison of electrode assemblies in a comparative example and the present disclosure. In the comparative example, an orthographic projection of the first transfer electrode 30 on the base substrate 95 is located within an orthographic projection of the first electrode 20 on the base substrate 95, the first electrode 20 has a length b′ in the first direction, and a distance a′ is provided between two adjacent electrode assemblies in the first direction. In the embodiment of the present disclosure, the first electrode 20 and the first transfer electrode 30 adopt the design in FIG. 3, a size of the electrode assembly formed by the first electrode 20 and the first transfer electrode 30 in the first direction is denoted by h1, and a distance between two adjacent electrode assemblies in the first direction is denoted by h. The liquid crystal efficiencies of the comparative example and the embodiment of the present disclosure are shown in table 1, from which it can be seen that the liquid crystal efficiency can be increased by means of the staggered design of the first electrode 20 and the first transfer electrode 30 in the embodiment of the present disclosure.

| | Comparative | | | |
|---|---|---|---|---|
| | Example | Present Embodiment | | |
| | a′/b′ (μm) | h/h1 (μm) | | |
| | 2/6 | 1/7 | 0.75/7.25 | 0.5/7.5 |
| Liquid crystal | 58% | 58.5% | 58.65% | 58.8% |
| efficiency | | | | |

As shown in FIGS. 3 to 5, the first via V1 has an opening toward the base substrate 95 and an opening away from the base substrate 95, and for convenience of description, the opening of each via toward the base substrate 95 will be referred to as the bottom opening of the via below, and the opening of the via away from the base substrate 95 will be referred to as the top opening of the via. An orthographic projection of the bottom opening of the first via V1 on the base substrate 95 is located within an orthographic projection of the top opening on the base substrate 95.

As shown in FIGS. 3 to 5, the main body part 21 includes a first edge E01 and a second edge E02 opposite to each other in the first direction, the first edge E01 is located on a side of the body part 21 away from the contact part 22, the second edge E02 is adjacent to the contact part 22, and the pixel region P has a size between 6 μm and 10 μm in the first direction. A distance f between the first edge E01 and the bottom opening of the first via V1 in the first direction is between 0 μm and 1.5 μm. For example, f is 0 μm, or 0.5 μm, or 1.0 μm, or 1.5 μm.

In the embodiment of the present disclosure, the orthographic projection of the first transfer electrode 30 on the base substrate 95 may have a rectangular shape, or may have other shapes such as a T shape.

FIG. 8 is a schematic diagram showing a part of a structure of an array substrate according to some other embodiments of the present disclosure. Similar to FIG. 3, the array substrate shown in FIG. 8 includes structures such as the thin film transistor, the first auxiliary layer 91, the second auxiliary layer 92, and the first electrode 20 described above. The differences lie in that, in FIG. 8, the first via V1 and the second via V2 are distributed in a staggered manner, the bottom opening of the first via V1 is not overlapped with an orthographic projection of the top opening of the second via V2 on the base substrate 95, the second transfer electrode 40 is electrically connected to the thin film transistor through the second via V2 running through the second auxiliary layer 92, and the second transfer part 32 of the first transfer electrode 30 is electrically connected to the second transfer electrode 40 through the first via V1, so that the second transfer electrode 40 electrically connects the first transfer electrode 30 to the drain region 11d of the thin film transistor. In addition, in FIG. 8, the second auxiliary layer 92 may include a first auxiliary sub-layer 921, and a second auxiliary sub-layer 922 on a side of the first auxiliary sub-layer 921 away from the base substrate 95. The data lines DL may be located between the first auxiliary sub-layer 921 and the second auxiliary sub-layer 922.

In FIG. 3, since the first via V1 is in communication with the second via V2 to form a deep hole with a large depth, which is desired to be filled with the auxiliary member 60 as a whole, so that a surface flatness of the auxiliary member 60 may be affected by process fluctuation. By means of the first via V1 and the second via V2 arranged in a staggered manner in FIG. 8, the auxiliary member 60 is required to fill only the first via V1, which is beneficial to improving the surface flatness of the auxiliary member 60. In addition, the first transfer electrode 30 and the second transfer electrode 40 may be two electrodes formed through two patterning processes, so that the fracture possibility of the first transfer electrode 30 and the second transfer electrode 40 can be reduced.

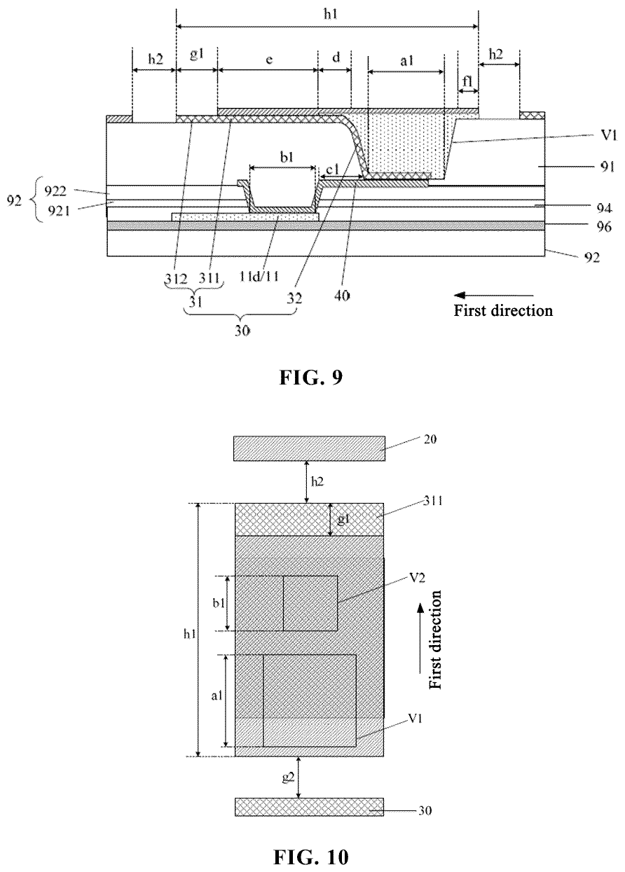

FIG. 9 is a schematic diagram showing relevant dimensions in the array substrate shown in FIG. 8, and FIG. 10 is a plan view of a first transfer electrode, a first electrode, a first via, and a second via in the array substrate shown in FIG. 8. Relevant parameters in FIG. 8 will be described below by taking a pixel region P of 6 μm*8 μm as an example.

As shown in FIGS. 8 to 10, the bottom opening of the first via V1 is substantially rectangular, and a length direction and a width direction thereof are the first direction and the second direction, respectively. In one example, the bottom opening of the first via V1 has a size al between 1.5 μm and 4 μm in the first direction, for example, 1.5 μm, or 2.0 μm, or 2.5 μm, or 3 μm, or 3.5 μm, or 4 μm. A size of the bottom opening of the first via V1 in the second direction may be equal to al, that is, the bottom opening of the first via V1 has a right-angled or rounded square shape.

As shown in FIGS. 8 to 10, the bottom opening of the second via V2 is substantially rectangular, and a length direction and a width direction thereof are the first direction and the second direction, respectively. In one example, the bottom opening of the second via V2 has a size b1 between 1.0 μm and 2.0 μm in the first direction, for example, 1.0 μm, or 1.5 μm, or 1.8 μm, or 2 μm. A size of the bottom opening of the second via V2 in the second direction may be equal to b1, that is, the bottom opening of the second via V2 has a right-angled or rounded square shape.

Similar to FIG. 3, the first transfer part 31 in FIG. 8 also includes a first portion 311 and a second portion 312, where the first portion 311 has a width e between 1 μm and 3 μm in the first direction, so that the secured connection between the first electrode 20 and the first transfer electrode 30 is ensured, and the length of the electrode assembly formed by the first electrode 20 and the first transfer electrode 30 is increased as much as possible. For example, e is 1 μm, or 1.5 μm, or 2 μm, or 2.5 μm, or 3 μm.

As shown in FIG. 9, a distance d between the first portion 311 and the top opening of the first via V1 the first direction is 0 μm to 3 μm, thereby ensuring sufficient filling of the auxiliary member 60 into the first via V1 without affecting the width e of the first portion 311. For example, d is 0 μm, or 0.5 μm, or 1 μm, or 1.5 μm, or 2 μm, or 2.5 μm, or 3 μm.

Compared with FIG. 3, the first via V1 and the second via V2 are staggered in FIG. 8, and an orthographic projection of the bottom opening of the first via V1 on the base substrate 95 is not required to cover an orthographic projection of the top opening of the second via V2 on the base substrate 95. Therefore, the first via V1 may have a smaller size, so that d, and thus the process window, can be increased properly.

As shown in FIG. 9, a distance cl between the bottom opening of the first via V1 and the top opening of the second via V2 in the first direction is between 0 μm and 1 μm. For example, cl is 0.1 μm, or 0.3 μm, or 0.5 μm, or 1.7 μm, or 0.8 μm, or 1.0 μm.

As shown in FIG. 9, the second portion 312 has a width g1 less than or equal to 1.5 μm in the first direction, so that the width e, and therefore the contact area between the first electrode 20 and the first transfer electrode 30, is increased as much as possible under a given length of the electrode assembly, thereby ensuring the secured connection between the first electrode 20 and the first transfer electrode 30. In one example, g1 is between 0.5 μm and 1.5 μm. For example, g1 is 0.5 μm, or 0.7 μm, or 0.9 μm, or 1.1 μm, or 1.3 μm, or 1.5 μm.

As shown in FIGS. 9 and 10, a first distance h2 is provided between the electrode assemblies of two adjacent pixel structures arranged in the first direction, and a ratio of the first distance h2 to a length h1 of each electrode assembly in the first direction is between 0.05 and 0.15. For example, the ratio of h2 to h1 is 0.05, or 0.07, or 0.09, or 0.1, or 0.11, or 0.13, or 0.15.

For example, in FIGS. 9 and 10, the first distance h2 is between 0.5 μm and 1.5 μm. For example, h2 is 0.5 μm, or 0.75 μm, or 1 μm, or 1.25 μm, or 1.5 μm. For example, h1 is 6.5 μm, or 7 μm, or 7.25 μm, or 7.5 μm.

As shown in FIGS. 8 to 9, the main body part 21 includes a first edge E01 and a second edge E02 opposite to each other in the first direction, the first edge E01 is located on a side of the body part 21 away from the contact part 22, the second edge E02 is adjacent to the contact part 22, and the pixel region has a size between 6 μm and 10 μm in the first direction. A distance f1 between the first edge E01 and the bottom opening of the first via V1 in the first direction is between 0.4 μm and 1.9 μm. For example, f1 is 0.4 μm, or 1.0 μm, or 1.5 μm, or 1.9 μm.

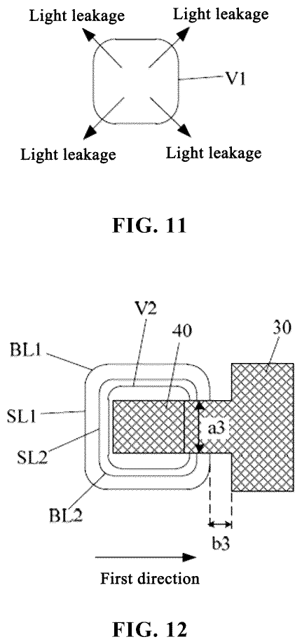

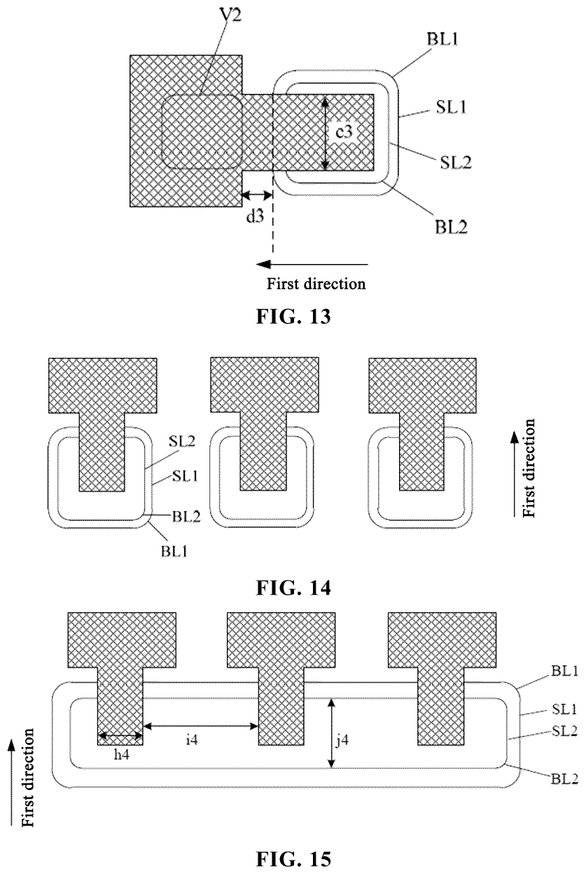

FIG. 11 is a schematic diagram showing a light leakage position of the first via, and FIGS. 12 and 13 are two plan views of a first transfer electrode, a first via, and a second via according to some embodiments of the present disclosure. As shown in FIG. 11, when the light-transmitting region of the mask used for fabricating the first via V1 has a right-angled rectangular shape, the top opening and the bottom opening of the resulted first via V1 each have a rounded rectangular shape due to the problem of exposure accuracy, and in a case where the first transfer electrode 30 contacts the rounded corners of the top opening and the bottom opening, light will be diffracted at the rounded corners, causing light leakage. To solve this problem, as shown in FIGS. 12 and 13, in some embodiments of the present disclosure, in a top view from the first auxiliary layer 91 to the base substrate 95, the top opening and the bottom opening of the resulted first via V1 each have a rounded rectangular shape. The top opening includes a plurality of first straight edges SL1 and a first arc edge BL1 connecting two adjacent first straight edges SL1. The bottom opening has a plurality of second straight edges SL2 and a second arc edge BL2 connecting two adjacent second straight edges SL2. The first transfer electrode 30 may contact one first straight edge SL1 and one second straight edge SL2, without contacting any first arc edge BL1 or second arc edge BL2, so that the first transfer electrode 30 is prevented from climbing from the rounded corner of the first via V1 to cause light leakage.

As shown in FIG. 12, where the first via V1 and the second via V2 are coaxially disposed and communicated with each other, the second transfer part 32 of the first transfer electrode 30 contacts one first straight edge SL1 and one second straight edge SL2 of the first via V1 without contacting any first arc edge BL1 or second arc edge BL2. In one example, a width a3 of the second transfer part 32 in the second direction is 0.25 to 0.9 times a length of a second straight edge SL2 in contact with the second transfer part 32. For example, a3 is 0.5 μm to 1.8 μm, and the length of the second straight edge SL2 in contact with the second transfer part 32 is 2 μm to 3 μm. In one example, the orthographic projection of the first transfer electrode 30 on the base substrate 95 includes a first projection region and a second projection region. The first projection region has a width a3 in the second direction, the second projection region has a width greater than a3 in the second direction, and a distance b3 between the second projection region and the first via V1 in the first direction is between 0 μm and 1 μm.

When the second projection region has a width greater than a3 in the second direction, the orthographic projection of the first transfer electrode 30 on the base substrate 95 is T-shaped. Apparently, in other examples, the second projection region may have a width equal to a3 in the second direction; that is, the orthographic projection of the first transfer electrode 30 on the base substrate 95 is rectangular.

As shown in FIG. 13, where the first via V1 and the second via V2 arranged in a staggered manner, the width c3 of the second transfer part 32 in the second direction is the same as a3. The orthographic projection of the first transfer electrode 30 on the base substrate 95 includes a first projection region and a second projection region. The first projection region has a width c3 in the second direction, the second projection region has a width c3+2*e3 in the second direction, where e3 is between 0.5 μm and 1.5 μm, and a distance d3 between the second projection region and the first via V1 in the first direction is between 0 μm and 1 μm.

FIG. 14 is a plan view of a plurality of first transfer electrodes and first vias in the same row according to some embodiments of the present disclosure, and FIG. 15 is a plan view of a plurality of first transfer electrodes and first vias in the same row according to some other embodiments of the present disclosure. As shown in FIG. 14, in some embodiments, the plurality of pixel structures are arranged in a plurality of rows, and first transfer electrodes 30 of the pixel structures are in one-to-one correspondence with first vias V1. That is, one first transfer electrode 30 is directly or indirectly connected to the drain region 11d of the thin film transistor through one first via V1. In other embodiments, however, as shown in FIG. 15, first vias V1 corresponding to the first transfer electrodes 30 of a plurality of pixel structures in the same row are communicated to form a strip-shaped via, so that the length of the straight edge of the via can be increased, and the contact between the first transfer electrode 30 and the rounded corner of the first via V1 can be avoided.

In one example, as shown in FIG. 15, a distance i4 in the row direction between second transfer parts 32 of two adjacent first transfer electrodes 30 in the same row is 0.5 to 10 times a width h4 of each second transfer part 32, so that a short circuit between two adjacent second transfer parts 32 in the same row is prevented while ensuring the secured connection between the second transfer parts 32. For example, i4 is 0.5 to 2 times, or 2 to 5 times, or 3 to 8 times, or 6 to 10 times of h4. The width h4 of the second transfer part 32 is a size of the second transfer part 32 in the second direction.

In one example, h4 is between 0.5 μm and 4 μm. For example, h4 is 0.5 μm, or 1 μm, or 1.5 μm, or 2 μm, or 2.5 μm, or 3 μm, or 3.5 μm, or 4 μm, and i4 is between 2 μm and 5 μm. For example, i4 is 2 μm, or 2.5 μm, or 3 μm, or 3.5 μm, or 4 μm, or 4.5 μm, or 5 μm.

In one example, a size j4 in the first direction of the bottom opening of the strip-shaped via formed by the plurality of first vias V1 communicated with each other is between 1.5 μm and 3.5 μm. For example, j4 is 1.5 μm, or 2 μm, or 2.5 μm, or 3 μm, or 3.5 μm.

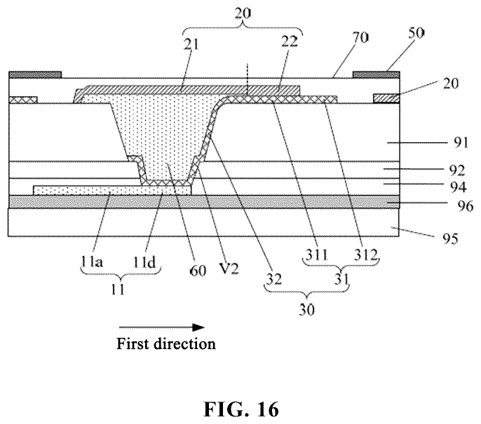

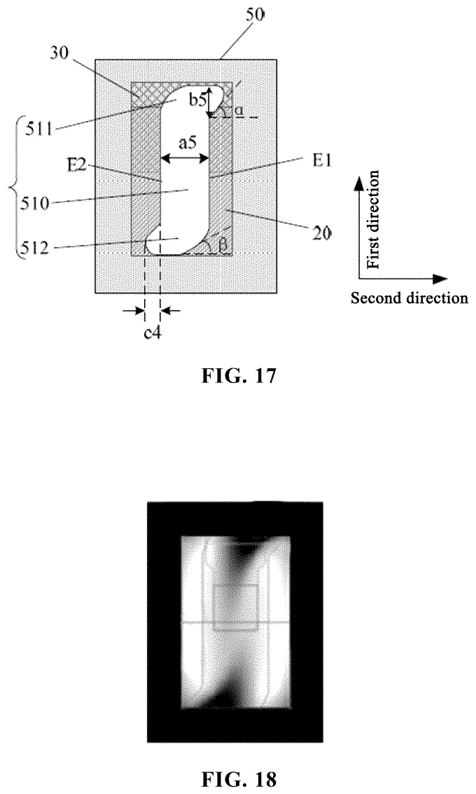

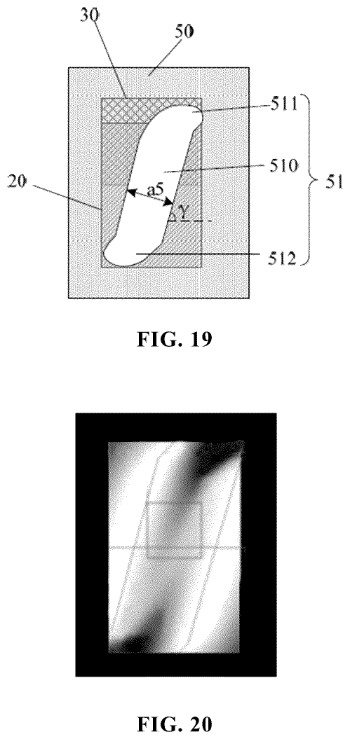

FIG. 16 is a schematic diagram of an array substrate provided with a second electrode layer according to some embodiments of the present disclosure, FIG. 17 is a plan view of a second electrode layer in a single pixel region relative to a first electrode and a first transfer electrode, FIG. 18 is a schematic diagram showing luminance distribution of the pixel region corresponding to FIG. 17, FIG. 19 is a plan view of a second electrode layer in a single pixel region relative to a first electrode and a first transfer electrode according to some other embodiments of the present disclosure, and FIG. 20 is a schematic diagram showing luminance distribution of the pixel region corresponding to FIG. 19.

As shown in FIG. 16, an insulating spacer layer 70 is disposed on a side of the first electrode 20 away from the base substrate 95, and the insulating spacer layer 70 may be made of a material selected from the materials listed above for the second auxiliary layer 92. The second electrode layer 50 is located on a side of the insulating spacer layer 70 away from the base substrate 95. The second electrode layer 50 being a common electrode layer is taken as an example for illustration in the embodiment of the present disclosure. As shown in FIGS. 17 and 19, the second electrode layer 50 is provided with a slit 51 including a main slit part 510, and a first corner part 511 and a second corner part 512 at two ends of, and in communication with, the main slit part 510, respectively. The main slit part 510 extends in a third direction. The first corner part 511 and the second corner part 512 are bent toward opposite sides of the main slit part 510, respectively.
and the first electrode 20 electrically connected to the first transfer electrode 30 form an electrode assembly, an orthographic projection of the main slit part 510 on the base substrate 95 is located within an orthographic projection of the electrode assembly on the base substrate 95, and orthographic projections of the first corner part 511 and the second corner part 512 on the base substrate 95 are both overlapped with the orthographic projection of the electrode assembly on the base substrate 95.

As shown in FIGS. 18 and 20, since the liquid crystal light efficiency is relatively low at an edge position of the pixel region, a dark region tends to be generated at the edge position of the pixel region, and by providing the first corner part 511 and the second corner part 512 at two ends of the slit 51, the position of the dark region can be shifted to the corner position of the pixel region, so that this part of dark region can be shielded by the black matrix in the display panel, thereby reducing the dark region area in the opening region and improving the transmittance.

In some examples, as shown in FIG. 17, the main slit part 510 has a width a5 between 0.5 μm and 3 μm in a direction perpendicular to the third direction. For example, a5 is 0.5 μm, or 1 μm, or 1.5 μm, or 2 μm, or 2.2 μm, or 2.7 μm, or 3 μm. The main slit part 510 includes a first side edge E1 and a second side edge E2 arranged in a width direction of the main slit part, the first corner part 511 is bent in a direction away from the second side edge E1 toward the first side edge E2, and the second corner part 512 is bent in a direction away from the first side edge E2 toward the second side edge E1.

In some examples, as shown in FIG. 17, the first corner part 511 has a size b5 between 1 μm and 1.5 μm in the first direction. For example, b5 is 1 μm, or 1.25 μm, or 1.5 μm. A region of the second corner 512 beyond the main slit part 510 has a width c4 between 0.5 μm and 1 μm in the second direction. For example, c4 is 0.5 μm, or 0.65 μm, or 0.75 μm, or 0.85 μm, or 1 μm.

In some examples, the first corner part 511 includes a first connecting edge connected to the first side edge, and an angle α of 30° to 60° is formed between a tangent line at a joint of the first connecting edge and the first side edge E1 and the second direction; the second corner part 512 includes a second connecting edge connected to the first side edge E1 and a third connecting edge connected to the second connecting edge, and an angle β of 15° to 30° is formed between a tangent line at an end of the third connecting edge away from the second connecting edge and the second direction; and the second direction is perpendicular to the first direction.

In some examples, as shown in FIG. 17, an extending direction of the main slit part 510 is parallel to the first direction. In other examples, as shown in FIG. 19, the extending direction of the main slit part 510 is intersected with the first direction. An angle γ between the extending direction of the main slit part 510 and the first direction is between 0° and 30°. For example, γ is 0°, or 10°, or 20°, or 30°.

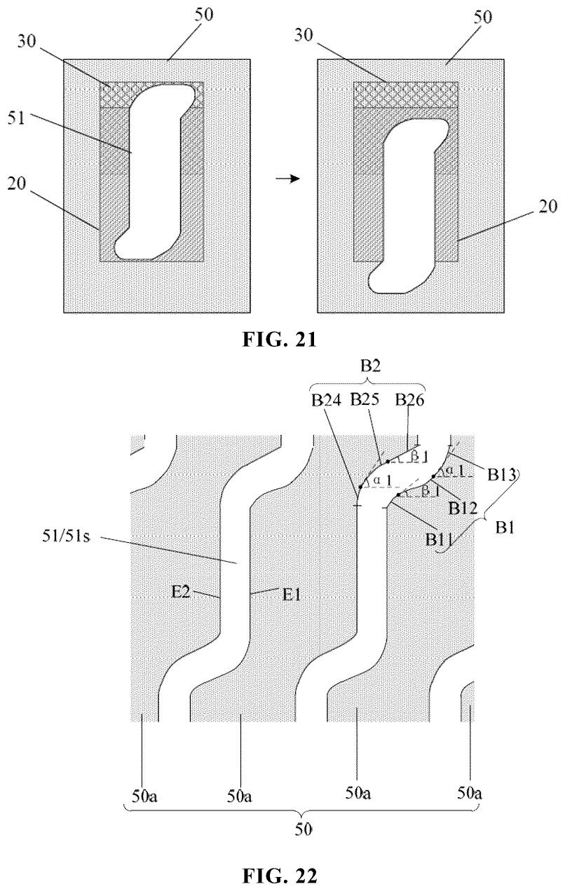

In some embodiments, the second electrode layer 50 is provided with the slit 51 at a position corresponding to each electrode assembly, and slits 51 corresponding to different electrode assemblies are not communicated with each other. However, in a product with a high pixel density, the pixel region has a relatively small size, and the alignment process of the second electrode layer 50 and the first electrode 20 is limited, with a deviation typically up to about 1 μm. FIG. 21 is a schematic diagram showing slits 51 in a second electrode layer 50 not misaligned and misaligned with an electrode assembly, respectively. As shown in FIG. 21, when the slit 51 is misaligned with the electrode assembly, the first corner parts 511 is moved toward the middle of the electrode assembly, resulting in a decreased transmittance of the pixel region. It has been found that the transmittance of the pixel region is decreased from 9.4% to 7.1% when misalignment occurs.

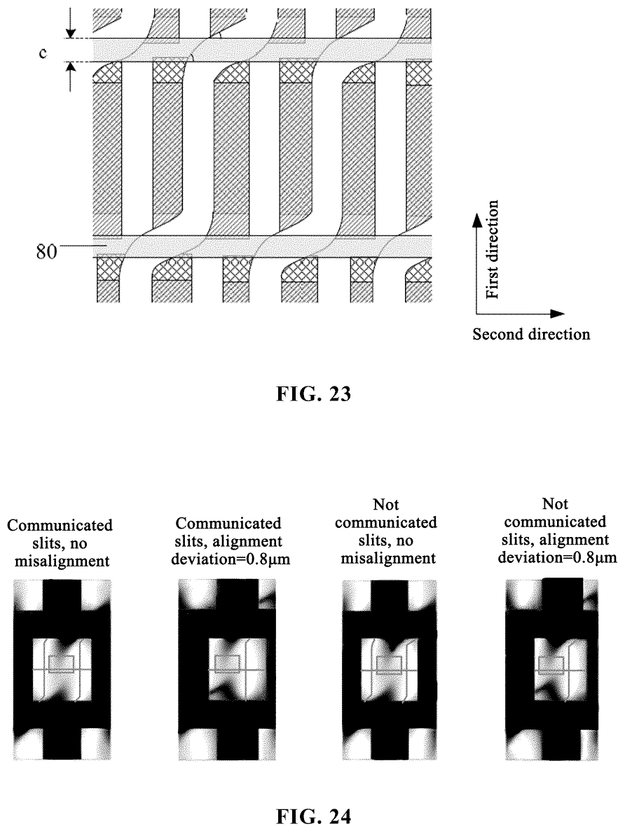

To improve the transmittance of the pixel region when the slit 51 is misaligned with the electrode assembly, in some embodiments of the present disclosure, slits 51 corresponding to the pixel regions may be communicated. FIG. 22 is a schematic diagram of a second electrode layer according to some embodiments of the present disclosure, and FIG. 23 is a diagram showing a superposition of a plurality of electrode assemblies, a second electrode layer and a connection electrode according to some embodiments of the present disclosure. As shown in FIGS. 22 to 23, in some embodiments of the present disclosure, the plurality of pixel structures are arranged in a plurality of rows in the first direction, each row including a plurality of pixel structures arranged in the second direction, and electrode assemblies of two adjacent rows of pixel structures are arranged in a staggered manner. The first corner part 511 of the slit 51 corresponding to at least one pixel structure is in communication with the second corner part 512 of the slit 51 corresponding to one pixel structure in a previous row, and the second corner part 512 of the slit 51 corresponding to at least one pixel structure is in communication with the first corner part 511 of the slit 51 corresponding to one pixel structure in a next row. When the second electrode layer 50 is misaligned with the electrode assembly, an electric field of a certain strength can still be formed at positions corresponding to the first corner part 511 and the second corner part 512 of the slit 51, thereby increasing the transmittance upon misalignment.

As shown in FIG. 22, for two slits 51 communicated with each other and respectively corresponding to two electrode assemblies in two adjacent rows, the main slit part 510 in a next row is located on a side, away from an extension line of the first side edge E1 in a previous row, of an extension line of the second side edge E2 of the main slit part 510 in the previous row. That is, for two slits 51 communicated with each other, the main slit part 510 in a next row is located on the lower left of the main slit part 510 in a previous row.

As shown in FIG. 22, the plurality of slits 51 are divided into a plurality of slit groups, the slits 51 in the same slit group are communicated with each other to form a dividing groove 51s, and a plurality of dividing grooves 51s corresponding to the plurality of slit groups divide the second electrode layer 50 into a plurality of second electrode strips 50a. The array substrate further includes a plurality of connection electrodes 80 each extending in the second direction and electrically connected to the plurality of second electrode strips 50a. A plurality of connection electrodes 80 may be used to electrically connect all the second electrode strips 50a, and may function to reduce a resistance of the second electrode layer 50. Each connection electrode 80 may be made of a metal material.

In some embodiments, orthographic projections of each connection electrode 80 and the main slit part 510 of the corresponding slit 51 on the base substrate 95 are not overlapped with each other. In some embodiments, each connection electrode 80 may have a width between 1.2 μm and 2.4 μm. For example, the width of the connection electrode 80 is 1.2 μm, or 1.3 μm, or 1.5 μm, or 1.8 μm, or 2.0 μm, or 2.2 μm, or 2.4 μm. The width of the connection electrode 80 refers to a size of the connection electrode 80 in a direction perpendicular to the second direction.

In some embodiments, for any two slits 51 communicated with each other, the second corner part 512 of the slit 51 in a previous row and the first corner part 511 of the slit 51 in a next row are communicated into a curved portion which includes a first curved edge B1 and a second curved edge B2 opposite to each other. As shown in FIG. 22, the first curved edge B1 is connected to first side edges E1 of two adjacent main slit parts 510, and the second curved edge B2 is connected to second side edges E2 of two adjacent main slit parts. The first curved edge B1 includes: a first connecting sub-edge B11, a second connecting sub-edge B12, and a third connecting sub-edge B13. The first connecting sub-edge B11 is connected to the first side edge E1 of the slit 51 in a next row, the third connecting sub-edge B13 is connected to the first side edge E1 of the slit 51 in a previous row, and the second connecting sub-edge B12 is connected between the first connecting sub-edge B11 and the third connecting sub-edge B13. The second curved edge B2 includes: a fourth connecting sub-edge B24, a fifth connecting sub-edge B25, and a sixth connecting sub-edge B26. The fourth connecting sub-edge B24 is connected to the second side edge E2 of the slit 51 in a next row, the sixth connecting sub-edge B26 is connected to the second side edge E2 of the slit 51 in a previous row, and the fifth connecting sub-edge B25 is connected between the fourth connecting sub-edge B24 and the sixth connecting sub-edge B26.

An angle β1 is formed between a tangent line at a junction of the second connecting sub-edge B12 and the first connecting sub-edge B11 and the second direction, where β1 is between 15° and 30°, and an angle α1 is formed between a tangent line at a junction of the second connecting sub-edge B12 and the third connecting sub-edge B13 and the second direction, where α1 is between 30° and 60°. The above angle α1 is also formed between a tangent line at a junction of the fifth connecting sub-edge B25 and the fourth connecting sub-edge B24 and the second direction. The above angle β1 is also formed between a tangent line at a junction of the sixth connecting sub-edge B26 and the fifth connecting sub-edge B25 and the second direction.

FIG. 24 is a diagram showing a simulation of light transmittances of a pixel region under different conditions. As shown in FIG. 24, in a case where the second electrode layer 50 is not misaligned, when the slits 51 in different pixel regions are not communicated, the transmittance of the pixel region is 9.3%; and when the slits 51 in the pixel region are communicated with the slits 51 in other pixel regions, the transmittance of the pixel region is increased to 9.5%. In a case where the second electrode layer 50 is misaligned with a deviation of 0.8 μm, when the slits 51 in different pixel regions are not communicated, the transmittance of the pixel region is 7.1% (which is decreased by 23% compared to the case of no misalignment); and when the slits 51 in the pixel region are communicated with the slits 51 in other pixel regions, the transmittance of the pixel region is 7.7% (which is decreased by 19% compared to the case of no misalignment). It can be seen that when the slits 51 in the pixel region is communicated with the remaining slits 51, the transmittance of the pixel region can be increased.

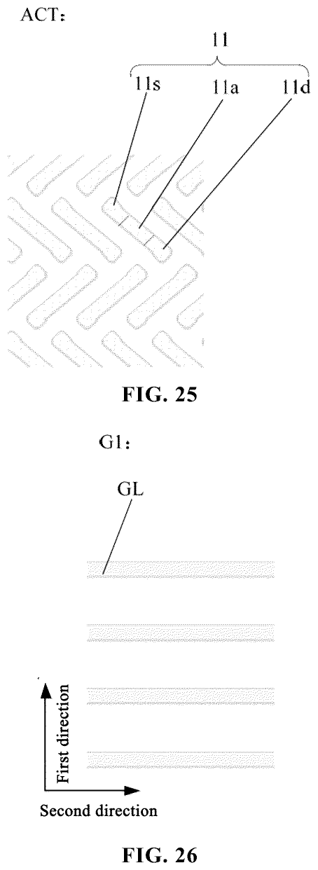

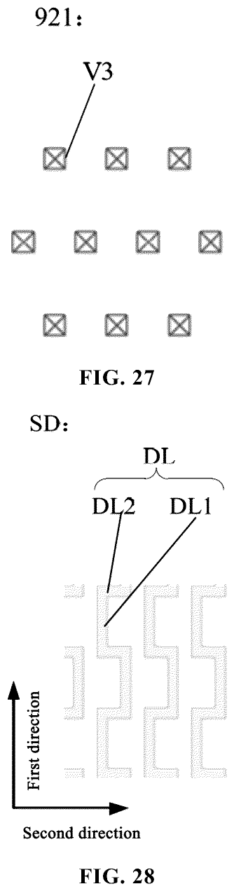

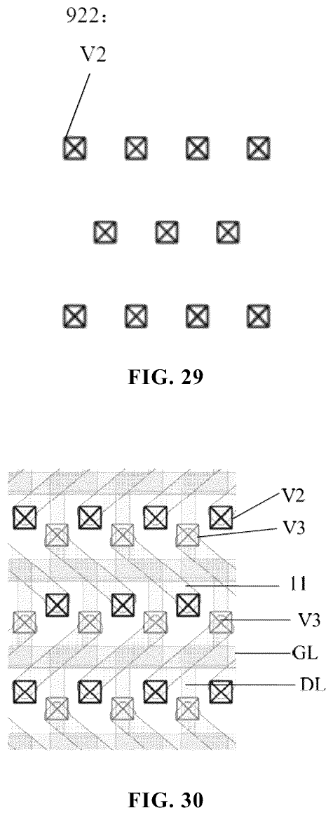

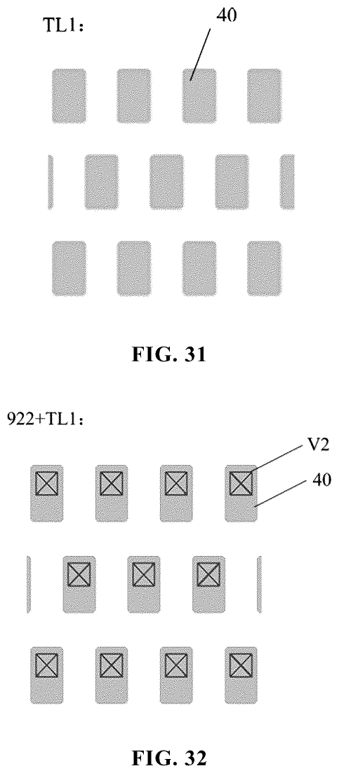

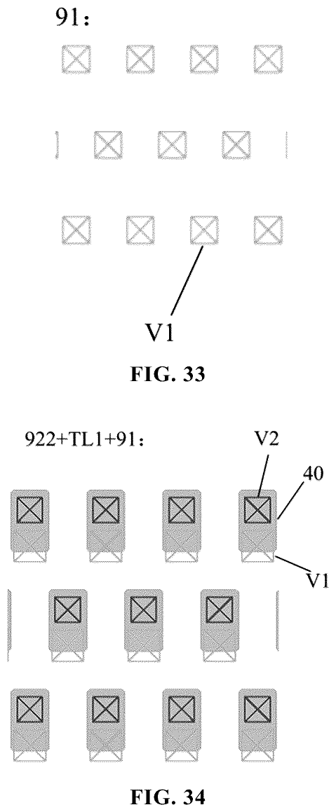

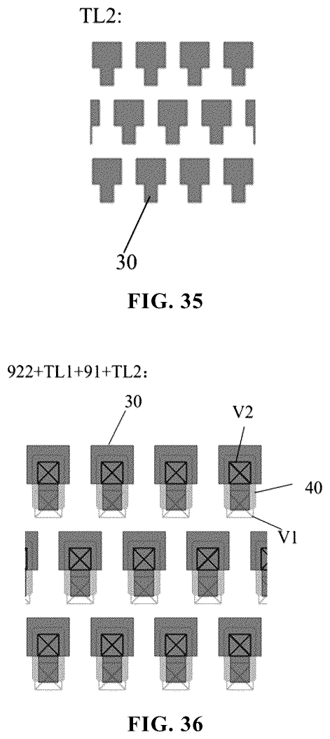

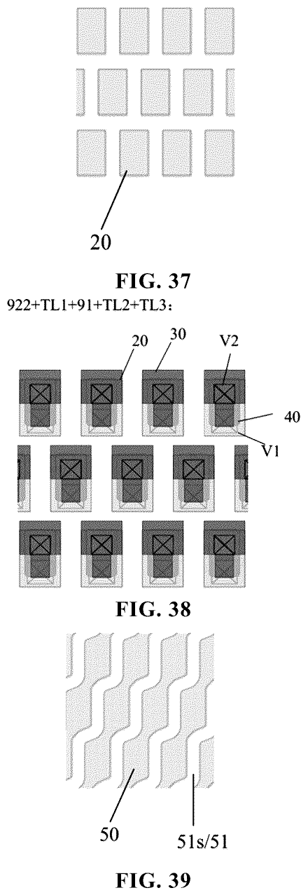

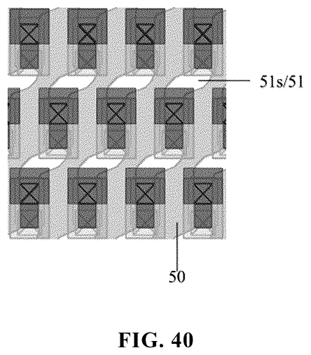

FIG. 25 is a plan view of a semiconductor layer according to some embodiments of the present disclosure, FIG. 26 is a plan view of a gate metal layer according to some embodiments of the present disclosure, FIG. 27 is a plan view of a first auxiliary sub-layer according to some embodiments of the present disclosure, FIG. 28 is a plan view of a source-drain metal layer according to some embodiments of the present disclosure, FIG. 29 is a plan view of a second auxiliary sub-layer according to some embodiments of the present disclosure, FIG. 30 is a diagram showing a superposition of a gate metal layer, a first auxiliary sub-layer, a source-drain metal layer, and a second auxiliary sub-layer according to some embodiments of the present disclosure, FIG. 31 is a plan view of a first transparent conductive layer according to some embodiments of the present disclosure, FIG. 32 is a diagram showing a superposition of a first transparent conductive layer and a second auxiliary sub-layer according to some embodiments of the present disclosure, FIG. 33 is a plan view of a first auxiliary layer according to some embodiments of the present disclosure, FIG. 34 is a diagram showing a superposition of a second auxiliary sub-layer, a first transparent conductive layer, and a first auxiliary layer according to some embodiments of the present disclosure, FIG. 35 is a plan view of a second transparent conductive layer according to some embodiments of the present disclosure, FIG. 36 is a diagram showing a superposition of a second auxiliary sub-layer, a first transparent conductive layer, a second transparent conductive layer, and a first auxiliary layer according to some embodiments of the present disclosure, FIG. 37 is a plan view of a third transparent conductive layer according to some embodiments of the present disclosure, FIG. 38 is a diagram showing a superposition of a second auxiliary sub-layer, a first transparent conductive layer, a second transparent conductive layer, a first auxiliary layer, and a third transparent conductive layer according to some embodiments of the present disclosure, FIG. 39 is a plan view of a second electrode layer according to some embodiments of the present disclosure, and FIG. 40 is a diagram showing a superposition of a second auxiliary sub-layer, a first transparent conductive layer, a second transparent conductive layer, a first auxiliary layer, a third transparent conductive layer, and a second electrode layer according to some embodiments of the present disclosure.

In the embodiment of the present disclosure, the pixel regions are arranged in a plurality of rows, the pixel regions in two adjacent rows are arranged in a staggered manner, and each pixel region corresponds to one thin film transistor, one first electrode 20, one first transfer electrode 30, and one second transfer electrode 40. As shown in FIG. 25, an active layer 11 of each thin film transistor is located in a semiconductor layer ACT, and the active layer 11 includes a channel region 11a, and a source region 11s and a drain region 11d on two sides of the channel region 11a. As shown in FIG. 26, a gate metal layer G1 includes a plurality of gate lines GL arranged in a first direction and each extending in a second direction. As shown in FIGS. 27 to 30, a first auxiliary sub-layer 921 is located on a side of the gate metal layer G1 away from the base substrate 95, and the first auxiliary sub-layer 921 is provided with a plurality of third vias V3 through which the source region 11 is of each thin film transistor is connected to the corresponding data line DL. A plurality of data lines DL are located in the source-drain metal layer SD, and arranged in the second direction. Each data line DL includes a first extension part DL1 extending in the first direction and a second extension part DL2 extending in the second direction. An orthographic projection of the second extension part DL2 on the base substrate 95 is overlapped with an orthographic projection of the corresponding gate line GL on the base substrate 95. The second auxiliary sub-layer 922 is located on a side of the source-drain metal layer SD away from the base substrate 95, and has a plurality of second vias V2.

As shown in FIGS. 31 to 40, a first transparent conductive layer TL1 is located on a side of the second auxiliary sub-layer 922 away from the base substrate 95, and includes a plurality of second transfer electrodes 40 in one-to-one correspondence with the plurality of pixel regions. Each second transfer electrode 40 is electrically connected to the drain region of the thin film transistor through the corresponding second via V2. A first auxiliary layer 91 is located on a side of the first transparent conductive layer TL1 away from the base substrate 95, and includes a plurality of first vias V1 in one-to-one correspondence with the plurality of pixel regions. A second transparent conductive layer TL2 is located on a side of the planarization layer 91 away from the base substrate, and includes a plurality of first transfer electrodes 30 in one-to-one correspondence with the plurality of pixel regions. Each first transfer electrode 30 is electrically connected to the second transfer electrode 40 through the corresponding first via V1. The shape of the first transfer electrode 30 is not limited, and for example, the first transfer electrode 30 may have a rectangular or trapezoidal shape. A third transparent conductive layer TL3 is located on a side of the second transparent conductive layer TL2 away from the base substrate 95, and includes a plurality of first electrodes 20 in one-to-one correspondence with the plurality of pixel regions. Each first electrode 20 is electrically connected to the corresponding first transfer electrode 30. A second electrode layer 50 is located on a side of the third transparent conductive layer TL3 away from the base substrate 95, and has a plurality of dividing grooves 51s, which are specifically described above.

An embodiment of the present disclosure further provides a display panel, including the array substrate according to any of the above embodiments, and an opposite substrate opposite to the array substrate.

The opposite substrate may include a color filter layer and a black matrix. The color filter layer includes color filter parts in one-to-one correspondence with the pixel regions. The plurality of color filter parts of the color filter layer may be divided into a plurality of repeated units each including various colors (e.g., red, green, and blue) of color filter parts, so that light from the plurality of pixel regions can emit different colors after passing through the color filter layer.

Orthographic projections of the gate lines GL, the data lines DL, and the connection electrodes 80 on the base substrate 95 are all located within an orthographic projection of the black matrix on the base substrate 95.

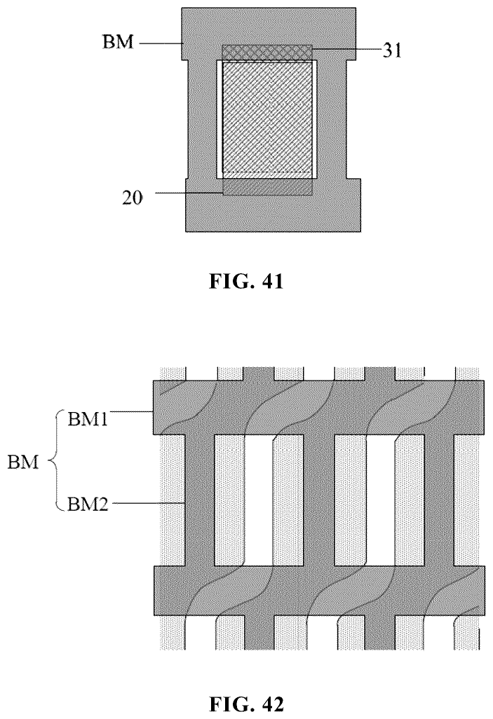

FIG. 41 is a plan view of a black matrix relative to a first electrode and a first transfer electrode according to some embodiments of the present disclosure, and FIG. 42 is a plan view of a black matrix relative to a second electrode layer according to some embodiments of the present disclosure. As shown in FIG. 41, an orthographic projection of the body part 21 of the first electrode 20 on the base substrate 95 is overlapped with the orthographic projection of the black matrix BM on the base substrate 95. An orthographic projection of the first transfer part 31 on the base substrate 95 is overlapped with the orthographic projection of the black matrix BM on the base substrate 95. Specifically, an orthographic projection of a portion of the first transfer part 31 beyond the first electrode 20 on the base substrate 95 is overlapped with the orthographic projection of the black matrix BM on the base substrate 95.

A portion of the pixel region which is not shielded by the black matrix BM serves as an opening region. The first via V1 is located in the opening region, which means that orthographic projections of the first via V1 and the black matrix BM on the base substrate 95 are not overlapped with each other, so that the shaded area by the black matrix BM is reduced, and the aperture ratio of the pixel region is increased.

As shown in FIG. 42, the black matrix BM includes a first shielding part BM1 extending in the first direction, and a second shielding part BM2 extending in the second direction. The second shielding part BM2 may have a width between 2.2 μm and 2.6 μm, for example, 2.2 μm, or 2.4 μm, or 2.8 μm. The first shielding part BM1 may have a width between 1.8 μm and 2.2 μm, for example, 1.8 μm, or 2 μm, or 2.2 μm. An orthographic projection of the first shielding part BM1 on the base substrate 95 is overlapped with an orthographic projection of the curved portion of the corresponding dividing groove 51s on the base substrate 95, and the orthographic projection of the first shielding part BM1 on the base substrate 95 is located between orthographic projections of main slit parts 510 in two adjacent rows on the base substrate 95.

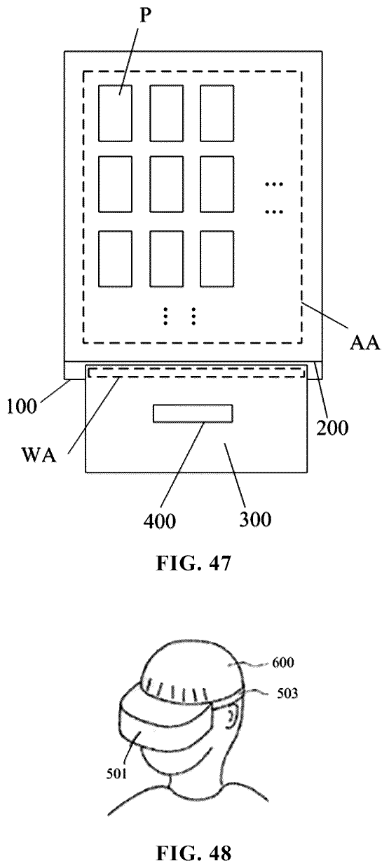

FIG. 47 is a schematic diagram of a display panel and a flexible printed circuit according to some embodiments of the present disclosure. As shown in FIG. 47, the display panel has a display region AA including a plurality of pixel regions P arranged in an array. The display panel includes an array substrate 100 and an opposite substrate 200 bonded by a sealant (not shown) applied around the display region AA. A bonding region WA is disposed on one side of the display region AA and provided with bonding pads. A flexible printed circuit 300 is bonded to the bonding pads, and provided with a driver chip 400 configured to provide a driving signal to each pixel region P.

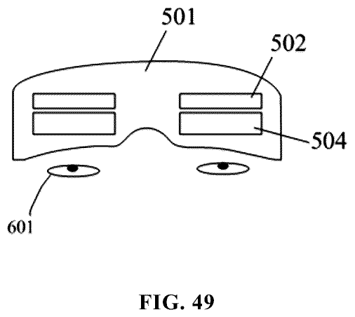

FIG. 48 is a schematic diagram of an application scenario of a display panel according to some embodiments of the present disclosure, and FIG. 49 is a schematic diagram of a near eye display device. As shown in FIGS. 48 and 49, the display panel may be applied to a near eye display device which includes a housing 501, a wearable part 503 connected to the housing 501, and a display part 502 and an optical system 504 in the housing 501. The wearable part 503 is configured to be worn on the head of a user 600, and the display part 502 may include the display panel in any of the above embodiments. The optical system 504 is configured to receive light from the display part 502, and project the light to user eyes 601 after refraction, reflection, or the like, so that the user 600 can see an image.

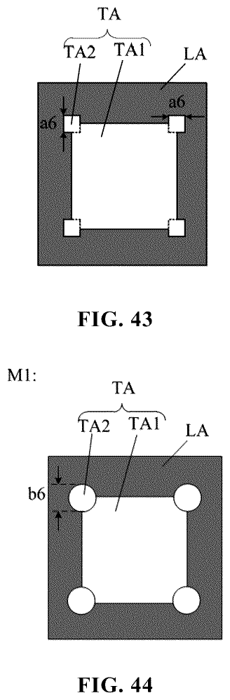

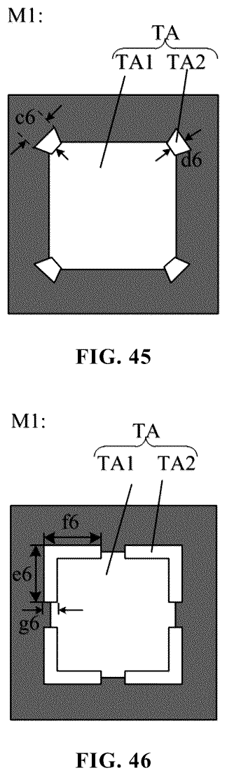

An embodiment of the present disclosure further provides a mask, which is applied to the method for manufacturing the array substrate and used for manufacturing the first via V1. FIG. 43 is a schematic diagram showing a part of a mask according to some embodiments of the present disclosure, FIG. 44 is a schematic diagram showing a part of a mask according to some other embodiments of the present disclosure, FIG. 45 is a schematic diagram showing a part of a mask according to yet other embodiments of the present disclosure, and FIG. 46 is a schematic diagram showing a part of a mask according to still other embodiments of the present disclosure.

As shown in FIGS. 43 to 46, the mask M1 includes a light-transmitting region TA for forming the first via V1, and a light-shielding region TA outside the light-transmitting region TA. An orthographic projection of the first via V1 on the base substrate 95 has substantially a polygonal shape, for example, a substantially rectangular shape. The term “substantially” a polygonal shape as used herein refers to a polygonal shape as a whole, such as a shape formed by two adjacent sides connected directly or through a rounded corner. The substantially rectangular shape may refer to a rounded rectangle, or a right-angled rectangle. Apparently, regardless of the number of sides of the polygon, the sides are not necessarily straight sides in a strict sense, and may have certain fluctuation due to process limitations. The light-transmitting region TA includes a main light-transmitting region TA1 and a compensation light-transmitting region TA2 communicated with each other. The main light-transmitting region TA1 has a polygonal shape, the compensation light-transmitting region TA2 is located at a corner of the main light-transmitting region TA1, and the compensation light-transmitting region TA2 protrudes out of edges of the main light-transmitting region TA1 in both a length direction and a width direction of the main light-transmitting region TA1.

The step of forming the first via V1 with the mask M1 includes: exposing the first auxiliary layer 91 with the mask M1 to denature a portion of the first auxiliary layer 91 corresponding to the light-transmitting region, and then developing the first auxiliary layer 91 to remove the denatured portion of the first auxiliary layer 91 and form a first via V1.

When the first via V1 is desired to be formed into a right-angled rectangular shape, if the light-transmitting region also has a right-angled rectangular shape, then light transmitted through corners of the right-angled rectangle will be less than through the middle of the right-angled rectangle, and therefore, the resulted pattern will be a rounded rectangle. For the first via V1 having a rounded rectangular shape, the first transfer electrode 30 tends to be fractured when climbing at a rounded corner of the first via V1.

In the mask M1 provided in the embodiment of the present disclosure, a compensation light-transmitting region TA2 is provided at each corner of the main light-transmitting region TA1, and protrudes out of edges of the main light-transmitting region TA1 in both a length direction and a width direction of the main light-transmitting region TA1, so that light transmitted through the corners of the main light-transmitting region TA1 can be increased, and the resulted first via V1 is closer to a right-angled rectangle.

The compensation light-transmitting region TA2 exceeds the main light-transmitting region TA1 in the length direction of the main light-transmitting region TA1 by a size of 0.02 to 0.2 times a length of the main light-transmitting region TA1; and the compensation light-transmitting region TA2 exceeds the main light-transmitting region TA1 in the width direction of the main light-transmitting region TA1 by a size of 0.02 to 0.2 times a width of the main light-transmitting region TA1.

For example, the length and width of the main light-transmitting region TA1 are both 2 μm to 3 μm, the compensation light-transmitting region TA2 exceeds the main light-transmitting region TA1 in the length direction of the main light-transmitting region TA1 by 0.05 μm to 0.4 μm, and the compensation light-transmitting region TA2 exceeds the main light-transmitting region TA1 in the width direction of the main light-transmitting region TA1 by 0.05 μm to 0.4 μm. For example, the main light-transmitting region TA1 has a square shape, i.e., has the length equal to the width.

For example, the main light-transmitting region TA1 has a square shape with a side length between 2 μm and 3 μm. As shown in FIG. 43, the compensation light-transmitting region TA2 may have a square shape, and an intersection point of two adjacent sides of the main light-transmitting region TA1 coincides with a center of the corresponding compensation light-transmitting region TA2. The compensation light-transmitting region TA2 has a side length a6 between 0.2 μm and 0.8 μm.

For example, the main light-transmitting region TA1 has a square shape with a side length between 2 μm and 3 μm. As shown in FIG. 44, the compensation light-transmitting region TA2 may have a circular shape, and an intersection point of two adjacent sides of the main light-transmitting region TA1 coincides with a center of the corresponding compensation light-transmitting region TA2. The compensation light-transmitting region TA2 has a diameter b6 between 0.2 μm and 0.8 μm.

For example, the main light-transmitting region TA1 has a square shape with a side length between 2 μm and 3 μm. As shown in FIG. 45, the compensation light-transmitting region TA2 may have a trapezoidal shape, and an intersection point of two adjacent sides of the main light-transmitting region TA1 coincides with a center of the corresponding compensation light-transmitting region TA2. The compensation light-transmitting region TA2 has a diameter b6 between 0.2 μm and 0.8 μm.

For example, the main light-transmitting region TA1 has a square shape with a side length between 2 μm and 3 μm. As shown in FIG. 46, the compensation light-transmitting region TA2 may have an L shape including a first strip part and a second strip part. An intersection point of midlines of the first strip part and the second strip part coincides with an intersection point of two adjacent sides of the main light-transmitting region TAL. A side length f6 of the first strip part and a side length e6 of the second strip part are both between 0.4 μm and 0.8, and the first strip part and the second strip part each have a width g6 between 0.1 μm and 0.4 μm.

It will be appreciated that the above implementations are merely exemplary implementations for the purpose of illustrating the principle of the present disclosure, and the present disclosure is not limited thereto. It will be apparent to one of ordinary skill in the art that various modifications and variations may be made without departing from the spirit or essence of the present disclosure. Such modifications and variations should also be considered as falling into the protection scope of the present disclosure.

1. An array substrate, comprising: a base substrate, and a first auxiliary layer and a plurality of pixel structures on the base substrate, wherein at least one of the pixel structures comprises:
a transistor between the first auxiliary layer and the base substrate;
a first transfer electrode comprising a first transfer part and a second transfer part connected to each other, wherein the first transfer part is on a side of the first auxiliary layer away from the base substrate, and the second transfer part is in a first via running through the first auxiliary layer to be electrically connected to the transistor;
an auxiliary member in the first via; and
a first electrode comprising a contact part and a body part connected to each other, wherein the contact part is electrically connected to the first transfer part, and an orthographic projection of the first electrode on the base substrate covers an orthographic projection of the first via on the base substrate;
wherein an orthographic projection of the first transfer part on the base substrate is overlapped with an orthographic projection of the contact part on the base substrate.

2. The array substrate according to claim 1, wherein the contact part contacts a surface of the first transfer part away from the base substrate, at least a part of the body part is on a surface of the auxiliary member away from the base substrate, and the second transfer part of the first transfer electrode is closer to the base substrate than the auxiliary member.

3. The array substrate according to claim 1, wherein at least one side boundary of the orthographic projection of the first transfer part on the base substrate exceeds the orthographic projection of the contact part on the base substrate.

4. The array substrate according to claim 3, wherein from a view perpendicular to the base substrate, a boundary of the orthographic projection of the first transfer part on the base substrate exceeds, along a first direction, a boundary of the orthographic projection of the contact part on the base substrate.

5. The array substrate according to claim 1, wherein the array substrate further comprises: a second auxiliary layer between the first auxiliary layer and the transistor; the at least one of the pixel structures further comprises: a second transfer electrode electrically connected to the transistor through a second via running through the second auxiliary layer;
wherein the second via is in communication with the first via, and the first transfer electrode and the second transfer electrode are connected into an integral structure, or
an orthographic projection of an opening of the first via facing the base substrate on the base substrate is not overlapped with an orthographic projection of an opening of the second via facing away from the base substrate on the base substrate.

6. (canceled)

7. The array substrate according to claim 1, wherein the array substrate has a plurality of pixel regions each provided with a corresponding pixel structure; a size of each pixel region in a first direction is greater than a size of the pixel region in a second direction perpendicular to the first direction; and
the contact part is on a side of the body part along the first direction.

8. The array substrate according to claim 7, wherein the first transfer part comprises a first portion and a second portion, wherein an orthographic projection of the first portion on the base substrate is within the orthographic projection of the contact part on the base substrate, the second portion is on a side of the first portion along the first direction, and an orthographic projection of the second portion on the base substrate is outside the orthographic projection of the contact part on the base substrate; and
a ratio of a size of the first portion to a size of the pixel region in the first direction is between 0.1 and 0.5.

9. The array substrate according to claim 2, wherein in a direction perpendicular to the base substrate, the auxiliary member has a height greater than or equal to a depth of the first via, and a distance between the body part of the first electrode and the base substrate is greater than a distance between the contact part and the base substrate.

10-11. (canceled)

12. The array substrate according to claim 7, wherein at least three of the pixel structures each comprise an electrode assemble comprising the first transfer electrode and the first electrode connected to the first transfer electrode in the corresponding pixel region, wherein a first distance is provided between electrode assemblies of two adjacent pixel structures arranged in the first direction, and a ratio of the first distance to a length of the electrode assembly in the first direction is between 0.05 and 0.15.

13. The array substrate according to claim 7, wherein the body part comprises a first edge and a second edge opposite to each other in the first direction, the first edge is on a side of the body part away from the contact part, the second edge is adjacent to the contact part, and the pixel region has a size between 6 μm and 10 μm in the first direction; and a distance between the first edge and an opening of the first via facing the base substrate in the first direction is between 0 μm and 1.5 μm.

14. The array substrate according to claim 1, wherein in a top view from the first auxiliary layer to the base substrate, an opening of the first via away from the base substrate has a plurality of first straight edges and a first arc edge connecting every two adjacent first straight edges; an opening of the first via close to the base substrate has a plurality of second straight edges and a second arc edge connecting every two adjacent second straight edges; and
the first transfer electrode is not in contact with the first arc edge and the second arc edge.

15. The array substrate according to claim 14, wherein the second transfer part contacts one of the second straight edges and one of the first straight edges, and a width of the second transfer part is 0.5 to 0.9 times a length of the one of the second straight edges in contact with the second transfer part.

16. The array substrate according to claim 1, wherein the pixel structures are in one-to-one correspondence with first vias in the first auxiliary layer; or,
the plurality of pixel structures are arranged in a plurality of rows, and the first vias corresponding to a plurality of pixel structures in the same row are communicated.

17. The array substrate according to claim 16, wherein the first vias corresponding to the plurality of pixel structures in the same row are communicated; and
a distance in the row direction between second transfer parts of two adjacent first transfer electrodes in the same row is 0.5 to 10 times a width of each second transfer part.

18. The array substrate according to claim 7, wherein the array substrate further comprises a second electrode layer provided with a slit comprising a main slit part, and a first corner part and a second corner part at two ends of, and in communication with, the main slit part, and the main slit part extends in a third direction; the first corner part and the second corner part are respectively bent towards two opposite sides of the main slit part;
the first transfer electrode forms an electrode assembly with the corresponding first electrode, an orthographic projection of the main slit part on the base substrate is within an orthographic projection of the electrode assembly on the base substrate, and orthographic projections of the first corner part and the second corner part on the base substrate are both overlapped with the orthographic projection of the electrode assembly on the base substrate.

19. (canceled)

20. The array substrate according to claim 18, wherein the main slit part comprises a first side edge and a second side edge arranged in a width direction of the main slit part, the first corner part is bent in a direction away from the second side edge toward the first side edge, and the second corner part is bent in a direction away from the first side edge toward the second side edge;
the first corner part comprises a first connecting edge connected to the first side edge, and an angle of 30° to 60° is formed between a tangent line at a joint of the first connecting edge and the first side edge and the second direction; the second corner part comprises a second connecting edge connected to the first side edge and a third connecting edge connected to the second connecting edge, and an angle of 15° to 30° is formed between a tangent line at an end of the third connecting edge away from the second connecting edge and the second direction; and the second direction is perpendicular to the first direction,
wherein an angle between the third direction and the first direction is in a range of [0°, 30°], and
the main slit part has a width between 0.5 μm and 3 μm in a direction perpendicular to the third direction.

21. (canceled)

22. The array substrate according to claim 18, wherein the second electrode layer is provided with the slit at a position corresponding to each electrode assembly,
the plurality of pixel structures are arranged in a plurality of rows in the first direction, each row comprising a plurality of pixel structures arranged in the second direction, the first corner part of the slit corresponding to at least one pixel structure is in communication with the second corner part of the slit corresponding to one pixel structure in a previous row, and the second corner part of the slit corresponding to at least one pixel structure is in communication with the first corner part of the slit corresponding to one pixel structure in a next row.

23. The array substrate according to claim 22, wherein a plurality of slits in the second electrode layer are divided into a plurality of slit groups, the slits in the same slit group are communicated with each other to form a dividing groove, and a plurality of dividing grooves corresponding to the plurality of slit groups divide the second electrode layer into a plurality of second electrode strips; and
the array substrate further comprises a plurality of connection electrodes extending in the second direction and electrically connected to the plurality of second electrode strips,
wherein orthographic projections of each connection electrode and the main slit part of the corresponding slit on the base substrate are not overlapped with each other.

24-25. (canceled)

26. A display panel, comprising the array substrate according to claim 1 and an opposite substrate opposite to the array substrate, the opposite substrate comprising a black matrix, wherein orthographic projections of the body part and the first transfer part on the base substrate are both overlapped with an orthographic projection of the black matrix on the base substrate, and/or
orthographic projections of the first via and the black matrix on the base substrate are not overlapped with each other.

27-28. (canceled)

29. A mask used in a method for manufacturing the array substrate according to claim 1, and the mask comprises: a light-transmitting region for forming the first via, wherein an orthographic projection of the first via on the base substrate has a substantially polygonal shape, the light-transmitting region comprises a main light-transmitting region and a compensation light-transmitting region communicated with each other, the main light-transmitting region has a polygonal shape, the compensation light-transmitting region is at a corner of the main light-transmitting region, and the compensation light-transmitting region protrudes out of edges of the main light-transmitting region in both a length direction and a width direction of the main light-transmitting region,
wherein the compensation light-transmitting region exceeds the main light-transmitting region in the length direction of the main light-transmitting region by a size of 0.02 to 0.2 time a length of the main light-transmitting region; and the compensation light-transmitting region exceeds the main light-transmitting region in the width direction of the main light-transmitting region by a size of 0.02 to 0.2 times a width of the main light-transmitting region.

30. (canceled)
